(19) United States
(12) Patent Application Publication
(10) Pub. No.: US 2007/0281246 A1
(43) Pub. Date: Dec. 6, 2007

(54) Processing method of light sensitive planographic printing plate material

(76) Inventor: Kazuhiko Hirabayashi, Tsukui-gun (JP)

Correspondence Address: CANTOR COLBURN, LLP, 55 GRIFFIN ROAD SOUTH, BLOOMFIELD, CT, 06002, US

(21) Appl. No.: 11/805,732

(22) Filed: May 24, 2007

(30) Foreign Application Priority Data
Jun. 2, 2006 (JP) JP2006-154413

(51) Int. Cl. G03F 7/00

(52) U.S. Cl. 430/302

(57) ABSTRACT

Disclosed is a processing method of a light sensitive planographic printing plate material comprising an aluminum support and provided thereon, a light sensitive layer containing an ethylenically unsaturated compound, a photopolymerization initiator and a polymeric binder, the method comprising the steps of imagewise exposing the light sensitive planographic printing plate material, induction heating the exposed light sensitive planographic printing plate material to a temperature of from 65 to 200° C., employing an induction heater, and developing the heated light sensitive planographic printing plate material.

This application is based on Japanese Patent Application No. 2006-154413 filed on Jun. 02, 2006 in Japanese Patent Office, the entire content of which is hereby incorporated by reference.

### FIELD OF THE INVENTION

The present invention relates to a processing method of a light sensitive planographic printing plate material used in a computer to plate (hereinafter referred to as CTP) system, and particularly to a processing method of a light sensitive planographic printing plate material used in a CTP system, comprising a step of induction heating.

### BACKGROUND OF THE INVENTION

In recent years, in a planographic printing plate making system, a CTP system has been developed in which digital image data is recorded directly in a light sensitive planographic printing plate material, employing a laser, and put into practical use.

In printing fields requiring relatively high printing durability, it is known that a negative working light sensitive planographic printing plate material is used which comprises a polymerizable light sensitive layer containing a polymerizable compound (see for example, Japanese Patent O.P.I. Publication Nos. 1-105238 and 2-127404).

Further, a light sensitive planographic printing plate material is known which is capable of being exposed employing a 390 to 430 nm laser and improves safelight properties in view of handling properties.

In recent years, a compact and high output blue-violet laser emitting a 390 to 430 nm light is easily obtainable. A light sensitive planographic printing plate material applied to this laser has been developed in order to enable processing under room light (see for example, Japanese Patent O.P.I. Publication Nos. 2000-35673, 2000-98605, and 2001-264978).

In an ordinary processing method of a light sensitive planographic printing plate material, an imagewise exposed light sensitive planographic printing plate material is heated (to about 110° C.) by a common heater, pre-washed with water to remove an over coat layer, developed, post-washed with water, subjected to gum processing, and dried, whereby a planographic printing plate is obtained. It is necessary in the above processing method that the common heater generates heat of a temperature of about 500° C. during processing, which results in loss of energy. Further, the common heater is difficult to apply uniform heat, which results in increase in dot gain, and is disadvantageous in obtaining prints requiring high resolution or high printing durability.

### SUMMARY OF THE INVENTION

The invention has been made in view of the above. An object of the invention is to provide a processing method of a light sensitive planographic printing plate material, the method being energy saving. Another object of the invention is to provide a processing method of a light sensitive planographic printing plate material providing a planographic printing plate with reduced dot gain, high resolution images and high printing durability.

### BRIEF DESCRIPTION OF THE DRAWING

FIG. 1 shows a structure of an induction heater used in the invention.

### DETAILED DESCRIPTION OF THE IN THE INVENTION

The above object of the invention can be attained by the following constitutions.

1. A processing method of a light sensitive planographic printing plate material comprising an aluminum support and provided thereon, a light sensitive layer containing an ethylenically unsaturated compound, a photopolymerization initiator, and a polymeric binder, the method comprising the steps of imagewise exposing the light sensitive planographic printing plate material, induction heating the exposed light sensitive planographic printing plate material at a temperature of from 65 to 200° C., employing an induction heater, and developing the heated light sensitive planographic printing plate material.

2. The processing method of item 1 above, wherein said imagewise exposing is carried out, employing a laser emitting light with an emission wavelength of from 350 to 450 nm.

3. The processing method of item 1 above, wherein said induction heating is carried out for from 5 to 30 seconds.

4. The processing method of item 1 above, wherein the photopolymerization initiator is a biimidazole compound.

5. The processing method of item 1 above, wherein the photopolymerization initiator is a polyhalogen compound.

6. The processing method of item 5 above, wherein the polyhalogen compound is a polyhaloacetyl compound represented by the following formula (I),

R¹¹—C X¹⁰)₂—(C═O)—R¹² Formula (I)

wherein X¹⁰ represents a chlorine atom or a bromine atom; R¹¹ represents a hydrogen atom, a chlorine atom, a bromine atom, an alkyl group, an aryl group, an acyl group, an alkylsulfonyl group, an arylsulfonyl group or a cyano group; and R¹² represents a monovalent substituent, provided that R¹¹ and R¹² may combine with each other to form a ring.

7. The processing method of item 1 above, wherein the light sensitive layer further contains a coumarin dye represented by the following formula (III),

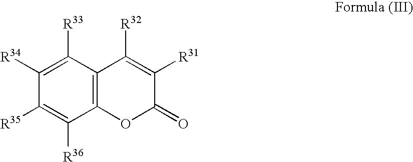

wherein R³¹, R³², R³³, R³⁴, R³⁵ and R³⁶ independently represent a hydrogen atom, an alkyl group, a cycloalkyl group, an alkenyl group, an alkinyl group, an aryl group, a heteroaryl group, a saturated heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sulfinyl group, an alkylsulfonyl group, an arylsulfonyl group, an amino group, a halogen atom, a cyano group, a nitro group or a hydroxyl group, provided that any adjacent two of R³¹, R³², R³³, R³⁴, R³⁵ and R³⁶ may combine with each other to form a ring.

8. A processing method of a light sensitive planographic printing plate material comprising an aluminum support and provided thereon, a light sensitive layer containing an ethylenically unsaturated compound, a photopolymerization initiator, and a polymeric binder, the method comprising the steps of imagewise exposing the light sensitive planographic printing plate material, developing the exposed light sensitive planographic printing plate material, and induction heating the developed light sensitive planographic printing plate material to a temperature of from 65 to 200° C., employing an induction heater.

9. The processing method of item 8 above, wherein said imagewise exposing is carried out, employing a laser emitting light with an emission wavelength of from 350 to 450 nm.

10. The processing method of item 8 above, wherein said induction heating is carried out for from 5 to 30 seconds.

11. The processing method of item 8 above, wherein the photopolymerization initiator is a biimidazole compound.

12. The processing method of item 8 above, wherein the photopolymerization initiator is a polyhalogen compound.

13. The processing method of item 12 above, wherein the polyhalogen compound is a polyhaloacetyl compound represented by the following formula (I),

R¹¹—C(X¹⁰)₂—(C═O)—R¹² Formula (I)

wherein X¹⁰ represents a chlorine atom or a bromine atom; R¹¹ represents a hydrogen atom, a chlorine atom, a bromine atom, an alkyl group, an aryl group, an acyl group, an alkylsulfonyl group, an arylsulfonyl group or a cyano group; and R¹² represents a monovalent substituent, provided that R¹¹ and R¹² may combine with each other to form a ring.

14. The processing method of item 8 above, wherein the light sensitive layer further contains a coumarin dye represented by the following formula (III),

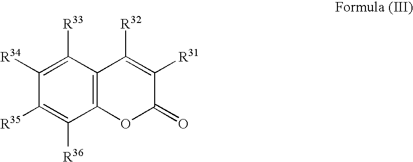

wherein R³¹, R³², R³³, R³⁴, R³⁵ and R³⁶ independently represent a hydrogen atom, an alkyl group, a cycloalkyl group, an alkenyl group, an alkinyl group, an aryl group, a heteroaryl group, a saturated heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sulfinyl group, an alkylsulfonyl group, an arylsulfonyl group, an amino group, a halogen atom, a cyano group, a nitro group or a hydroxyl group, provided that any adjacent two of R³¹, R³², R³³, R³⁴, R³⁵ and R³⁶ may combine with each other to form a ring.

The invention will be explained in detail below.

In the invention, heating is not carried out by a common heater, but induction heating is carried out employing an induction heater. In the invention, an exposed planographic printing plate material or an exposed and developed planographic printing plate material is induction heated employing an induction heater. The developed planographic printing plate material is ordinarily subjected to post-processing, whereby a planographic printing plate is obtained. The induction heating in the invention consumes power only during processing, resulting in energy-saving. Further, in the induction heating, uniform heating is carried out, providing a planographic printing plate with high image quality and high printing durability.

### (Induction Heating)

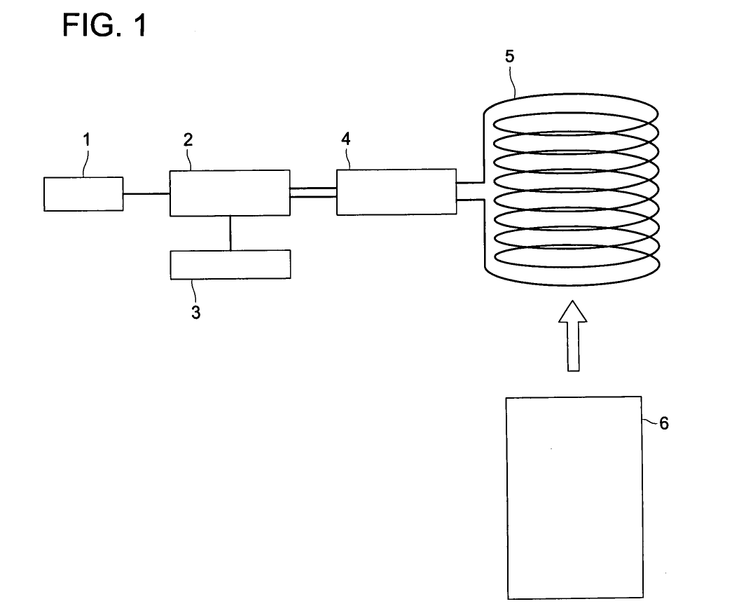

Next, the induction heating in the invention will be explained employing FIG. 1.

FIG. 1 shows a structure of an induction heater in the invention. In FIG. 1, power is supplied from a three phase 200 V power source 1 to a high frequency power source 2, where a high frequency of from 1 kHz to 1 MHz is produced. The high frequency power source 2 is cooled with a chilled water circulation cooler 3. The high frequency produced in the high frequency source 2 is supplied to a high frequency transformer 4 and then to a heat coil 5. A light sensitive planographic printing plate material 6 (exposed or exposed and developed) is transported, as shown in an arrow, into the heat coil 5, where the light sensitive planographic printing plate material comprising a metal (aluminum) support is induction heated. The light sensitive planographic printing plate material is heated at from 65 to 200° C. in the heat coil and then is ejected from the coil. The light sensitive planographic printing plate material is heated at preferably from 70 to 180° C., and more preferably from 80 to 120° C. in the heat coil. The heating period is preferably from 1 to 60 seconds, more preferably from 5 to 30 seconds, and still more preferably from 15 to 25 seconds, although it is different due to a size of light sensitive planographic printing plate material. The high frequency is preferably from 10 kHz to 500 kHz.

### (Imagewise Exposure)

As a light source for recording an image on the light sensitive planographic printing plate material of the invention, a laser having an emission wavelength of from 350 to 450 nm is preferably used.

Examples of such a laser include a He—Cd laser (441 nm), a combination of Cr:LiSAF and SHG crystals (430 nm) as a solid laser, and KnbO3, ring resonator (430 nm), AlGaInN (350-350 nm) or AlGaInN semiconductor laser (InGaN type semiconductor laser available on the market, 400-410 nm) as a semiconductor type laser.

When a laser is used for exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

As a laser scanning method of lasers used in the invention, there are a method of laser scanning on an outer surface of a cylinder, a method of laser scanning on an inner surface of a cylinder and a method of laser scanning on a plane. In the method of laser scanning on an outer surface of a cylinder, laser beam exposure is conducted while a drum around which a recording material is wound is rotated, in which main scanning is represented by the rotation of the drum, while sub-scanning is represented by the movement of the laser beam. In the method of laser scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of laser scanning on a plane, main scanning by means of a laser beam is carried out through a combination of a polygon mirror, a galvano mirror and an FO lens, and sub-scanning is carried out moving a recording medium. The cylinder outer surface laser scanning method and the cylinder inner surface laser scanning method are suitable for high density image recording, since it is easier to increase accuracy of an optical system. The cylinder outer surface laser scanning method is especially preferred in employing laser energy effectively, and in designing easily the optical system including the laser used.

In the invention, imagewise exposure is carried out at a plate surface energy (an exposure energy at the surface of the planographic printing plate material) of from 10 to 500 mJ/cm², and more preferably from 10 to 300 mJ/cm². This exposure energy can be measured, employing a laser power meter PDGDO-3W produced by Ophir Optronics Inc.

### (Development)

In the invention, the imagewise exposed light sensitive layer, which are cured are at exposed portions, is developed with a developer, whereby the light sensitive layer at unexposed portions are removed to form an image.

As such a developer, a conventional alkali aqueous solution is used. For example, there is an alkali developer containing an inorganic alkali agent such as sodium silicate, potassium silicate, ammonium silicate, sodium secondary phosphate, potassium secondary phosphate, ammonium secondary phosphate; sodium hydrogen carbonate, potassium hydrogen carbonate, ammonium hydrogen carbonate; sodium carbonate, potassium carbonate, ammonium carbonate; sodium borate, potassium borate, lithium borate; sodium hydroxide, potassium hydroxide, and ammonium hydroxide.

The alkali developer can contain organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine.

These alkali agents can be used singly or as a mixture of two or more thereof. The alkali developer can contain an anionic surfactant, an amphoteric surfactant, or an organic solvent such as alcohol.

### (Developer Concentrate)

The alkali developer is preferably prepared from a developer concentrate such as a developer in the form of tablets or granules.

In the invention, it is advantageous to use such a developer concentrate. The developer concentrate is preferably used as a developer or a developer replenisher after it is dissolved in water to give a prescribed concentration.

The developer concentrate may be prepared by providing a developer solution, followed by evaporation to dryness and is preferably prepared in such a manner that plural components are mixed with a small amount of water or without adding any water. The developer concentrate can also be prepared in the form of granules or tablets, as described in Japanese Patent O.P.I. Publication Nos. 51-61837, 2-109042, 2-109043, 3-39735, 5-142786, 6-266062 and 7-13341. The developer concentrate may be divided into plural parts differing in material species or compounding ratio.

The concentrate is used for development preferably by diluting with water to a prescribed concentration prior to development. When the developer concentrate is used as a developer replenisher, it is preferred that the developer concentrate is diluted with water to a prescribed concentration, followed by being supplied to a working developer, whereby it is also feasible to supply a developer at a higher concentration than the prescribed one or, without being diluted to the prescribed concentration, to the working developer. When supplied at a higher concentration than the prescribed one or without being diluted to the prescribed concentration, water may be separately added in the same timing or in a different timing.

The developer concentrate has a water content of preferably not more than 10% by weight, and more preferably not more than 1% by weight, based on the concentrate. The higher water content often causes problems such that developer components separate out in water, losing homogeneity or becomes liquid, making handling hard. Components contained in a developer for a conventional lithographic printing plate material can be employed as the components for the developer concentrate and it is preferred to exclude a component which reacts at a water content of not more than 10% by weight and cannot be recovered even with dilution, a material having a large moisture content or a liquid material at ordinary temperature. For example, a silicate petrifies at a reduced water content and becomes hard to be solved. Therefore, carbonates, phosphates or organic acid salts described later are contained in the developer concentrate instead of silicates. Carbonates are especially preferred.

Components contained in the developer concentrate will be explained below. Explanation is made on those of both developer concentrate and developer replenisher concentrate, unless otherwise specified. The term “developer” refers to a developer or developer replenisher after the concentrate has been diluted with a given amount of water.

### (Alkali Reagent)

Examples of an inorganic alkali reagent include sodium tertiary phosphate, potassium tertiary phosphate, ammonium tertiary phosphate, sodium carbonate, potassium carbonate, ammonium carbonate, sodium hydrogen carbonate, potassium hydrogen carbonate, ammonium hydrogen carbonate, sodium borate, potassium borate, ammonium borate, sodium hydroxide, potassium hydroxide, ammonium hydroxide, and lithium hydroxide. Examples of an organic alkali reagent include monomethhylamine, dimethylamine, trimethylamine, monoethylamine, diethylamine, triethylamine, monoisobutylamine, diisobutylamine, triisobutylamine, n-butylamine, monoethanolamine, diethanolamine, triethanolamine, monoisopropanolamine, diisopropanolamine, ethyleneimine, ethylenediamine, pyridine, and tetramethylammonium hydroxide.

The alkali reagents can be used alone or in combination thereof. An alkali reagent is used preferably in an amount giving a pH of 9 to 13.5, and more preferably 10.0 to 12.5, and an electric conductivity of 2 to 40 mS/cm, more preferably 3 to 30 mS/cm, and still more preferably 5 to 20 mS/cm) when used as a developer (or developer solution). A pH lower than the foregoing range results in no image formation and a pH exceeding the foregoing range often causes over-development, leading to increased damages in development at exposed areas. A conductivity lower than the foregoing range usually renders difficult dissolution of the light sensitive layer provided on the surface of an aluminum plate support, leading to stained printing. A conductivity exceeding the foregoing range results in an increased salt concentration, retarding dissolution of the light sensitive layer, resulting in residual layer at unexposed areas.

The developer concentrate in the invention preferably contains a nonionic surfactant having a polyoxyalkylene ether group. Addition of such a surfactant promotes dissolution of the light sensitive layer in unexposed areas and minimizes penetration of a developer to exposed areas. As the surfactant having a polyoxyalkylene ether group is suitably used a compound represented by the following formula (AO):

R₁—O—(R₂—O)ₙH Formula (AO)

wherein R₁ is an alkyl group having 3 to 15 carbon atoms, an aromatic hydrocarbon group having 6 to 16 carbon atoms or an aromatic heterocyclic group having 4 to 15 carbon atoms, each of which may have a substituent, (examples of the substituent include an alkyl group having 1 to 20 carbon atoms, a halogen atom such as Br, Cl or I, an aromatic hydrocarbon group having 6 to 15 carbon atoms, an aralkyl group having 7 to 17 carbon atoms, an alkoxy group having 1 to 20 carbon atoms, an alkoxycarbonyl group having 2 to 20 carbon atoms and an acyl group having 2 to 15 carbon atoms); R₂ is an alkylene group having 1 to 100 carbon atoms, which may have a substituent (examples of the substituent include an alkyl group having 1 to 20 carbon atoms and an aromatic hydrocarbon group having 6 to 15 carbon atoms); and n is an integer of 1 to 100.

In formula (AO), (R₂—O)ₙ may be comprised of a combination of two or three kinds thereof, as long as it falls within the above-described range. Typical examples thereof include those in which a combination of an ethylene oxy group and a propyleneoxy group, an ethylene oxy group and an isopropyleneoxy group, an ethylene oxy group and butyleneoxy group, or an ethylene oxy group and an isobutyleneoxy group is arranged randomly or in block form.

Surfactants having a polyoxyalkylene ether group, which may be used alone or in their combination, are added to a developer, preferably in an amount of 1 to 30%, and more preferably 2 to 20 % by weight. A lesser addition amount lowers developability and an excessive addition results in increased damages in development, leading to lowering of printing durability of printing plate.

There may be incorporated other surfactants. Examples thereof include nonionic surfactants including polyoxyethylene alkyl ethers such as polyoxyethylene lauryl ether, polyoxyethylene cetyl ether and polyoxyethylene stearyl ether; polyoxyethylene alkylaryl ethers such as polyoxyethylene octylphenyl ether and polyoxyethylene nonylphenyl ether; polyoxyethylene alkyl esters such as polyoxyethylene stearate; sorbitan alkyl esters such as sorbitan monolaurate, sorbitan monostearate, sorbitan distearate and sorbitan trioleate; monoglyceride alkyl esters such as glycerol monostearate and glycerol monooleate: anionic surfactants including alkylbebzenesulfonates such as sodium dodecylbenzenesulfonate; alkylnaphthalenesulfonates such as sodium butylnaphthalenesulfonate, sodium pentylnaphthalenesulfonate, sodium hexylnaphthalenesulfonate and sodium octylnaphthalenesulfonate; alkylsulfates such as sodium laurylsulfate; alkyl sulfonates such as sodium dodecylsulfonate; sulfosuccinic acid esters such as sodium dilaurylsulfosuccinate: amphoteric surfactants including alkylbetaines such as laurylbetaine and allylbetaine; and amino acids. Of these surfactants, anionic surfactants such as alkylnaphthalenesulfonates are specifically preferred.

These surfactants may be used alone on in their combination. These surfactants are preferably contained in an effective amount (in terms of solids) of 0.1 to 20% by weight.

In addition to the components described above, the developer concentrate in the invention may optionally contain additives such as an organic solvent, a chelating agent, a reducing agent, dye, pigment, a water-softening agent, an antiseptic agent and a defoaming agent.

### (Development Stabilizing Agent)

The developer concentrate preferably contains a development stabilizing agent. The preferred examples of the development stabilizing agent include an adduct of sugar alcohol with polyethylene glycol, tetraalkylammonium hydroxide such as tetrabutylammonium hydroxide, a phosphonium salt such as tetrabutylphosphonium bromide, and an iodonium salt such as diphenyliodonium chloride, as disclosed in Japanese Patent O.P.I. Publication No. 6-282079. Examples of the development stabilizing agent include anionic surfactants or amphoteric surfactants disclosed in Japanese Patent O.P.I. Publication No. 50-51324, water soluble cationic polymers disclosed in Japanese Patent O.P.I. Publication No. 55-95946, and water soluble amphoteric surfactants disclosed in Japanese Patent O.P.I. Publication No. 56-142528. Further, the examples include organic boron-containing compound to which alkylene glycol is added, disclosed in Japanese Patent O.P.I. Publication No. 59-84241, polyoxyethylene-polyoxypropylene block polymer type water-soluble surfactant, disclosed in Japanese Patent O.P.I. Publication No. 60-111264, an alkylenediamine compound having polyoxyethylene-polyoxypropylene, disclosed in Japanese Patent O.P.I. Publication No. 60-129750, polyoxyethylene, glycol with an average weight molecular weight of not less than 300 disclosed in Japanese Patent O.P.I. Publication No. 61-215554, a fluorine-containing surfactant having a cationic group disclosed in Japanese Patent O.P.I. Publication No. 63-175858, and a water soluble ethyleneoxide adduct obtained by adding ethyleneoxy to an acid or an alcohol, or water soluble polyalkylenes disclosed in Japanese Patent O.P.I. Publication No. 2-39157.

### (Organic Solvent)

Organic solvents are optionally added to a developer or a developer replenisher. The organic solvent is a solvent having a solubility in water of suitably 10 weight % or less, and preferably 5 weight % or less. Examples of the organic solvent include 1-phenylethanol, 2-phenylethanol, 3-phenyl-1-propanol, 4-phenyl-1-butanol, 1-phenyl-2-butanol, 2-phonoxyethanol, 2-benzyloxyethanol, o-methoxybenzylalcohol, m-methoxybenzylalcohol, p-methoxybenzylalcohol, benzylalcohol, cyclohexanol, 2-methylcyclohexanol, 3-methylcyclohexanol, 4-methylcyclohexanol, N-phenylethanolamine, and N-phenyldiethanolamine. The organic solvent content of the working developer is preferably 0.1 to 5 weight %. It is preferred that the organic solvent content is not substantially contained in the developer or developer replenisher. The term “not substantially contained” means that the organic solvent is contained in an amount of not more than 1% by weight.

### (Reducing Agent)

A reducing agent is optionally added to the developer concentrate used in the invention. This is added in order to prevent occurrence of stains on the printing plate during printing. The addition is particularly effective in developing a negative working light sensitive planographic printing plate material comprising a light sensitive diazonium compound. Preferred examples of the reducing agent include a phenolic compound such as thiosalicylic acid, hydroquinone, metol, methoxyquinone, resorcine, or 2-methylresorcine, and an amine compound such as phenylenediamine or phenylhydrazine. Preferred examples of the inorganic reducing agent include a sodium, potassium or ammonium salt of an inorganic acid such as sodium sulfite, potassium sulfite, ammonium sulfite, sodium phosphite, potassium phosphite, ammonium phosphite, sodium hydrogen phosphite, potassium hydrogen phosphite, ammonium hydrogen phosphite, sodium thiosulfate, potassium thiosulfate, ammonium thiosulfate, sodium dithionite, potassium dithionite, ammonium dithionite. It is sulfite of these that shows excellent anti-staining effect. The reducing agent content of the developer is preferably 0.05 to 5% by weight.

### (Organic Carboxylic Acid)

An organic carboxylic acid is optionally added to the developer concentrate used in the invention. Preferred organic carboxylic acids include an aliphatic carboxylic acid or an aromatic carboxylic acid each having a carbon atom number of from 6 to 20.

Examples of the aliphatic carboxylic acid include caproic acid, enanthic acid, caprylic acid, lauric acid, myristic acid, palmitic acid, and stearic acid. Particularly preferred are alkanoic acids having a carbon atom number of from 8 to 12. The acid may be an unsaturated acid having a double bond in the molecule or may have a branched carbon chain. The aromatic carboxylic acid is an aromatic compound such as benzene, naphthalene or anthracene having a carboxyl group. Examples of the aromatic carboxylic acid include o-chlorobenzoic acid, p-chlorobenzoic acid, o-hydroxybenzoic acid, p-hydroxybenzoic acid, o-aminobenzoic acid, p-aminobenzoic acid, 2,4-dihydroxybenzoic acid, 2,5-dihydroxybenzoic acid, 2,6-dihydroxybenzoic acid, 2,3-dihydroxybenzoic acid, 3,5-dihydroxybenzoic acid, gallic acid, 1-hydroxy-2-naphthoic acid, 3-hydroxy-2-naphthoic acid, 2-hydroxy-1-naphthoic acid, 1-naphthoic acid, and 2-naphthoic acid. Hydroxy naphthoic acids are especially preferred. These carboxylic acids are preferably used in the salt form, for example as the sodium salts, potassium salts or ammonium salts, in order to increase their water solubility. The organic carboxylic acid content of the developer is not specifically limited, but the content lass than 0.1% by weight does not exhibit advantageous effects, while the content exceeding 10% by weight cannot enhance the effects and may prevent dissolution of other additives into the developer. Therefore, the organic carboxylic acid content of the working developer is preferably from 0.1 to 10% by weight, and more preferably from 0.5 to 4% by weight.

### (Other Additives)

The developer concentrate in the invention may contain the following additives in order to increase development performance. Examples of the additives include a neutral salt such as sodium chloride, potassium chloride, potassium bromide, as disclosed in Japanese Patent O.P.I. Publication No. 58-75152, a complex such as [Co(NH₃)₆]Cl₃ as dislosed in Japanese Patent O.P.I. Publication No. 59-121336, an amphoteric polymer such as a copolymer of vinylbenzyl-trimethylammonium chloride and sodium acrylate as disclosed in Japanese Patent O.P.I. Publication No. 56-142258, the organic metal containing surfactant containing Si or Ti as disclosed in Japanese Patent O.P.I. Publication No. 59-75255, and the organic boron containing compound disclosed in Japanese Patent O.P.I. Publication No. 59-84241.

The developer or developer replenisher in the invention can further contain an antiseptic agent, a coloring agent, a viscosity increasing agent, an antifoaming agent, or a water softener. Examples of the antifoaming agent include mineral oil, vegetable oil, alcohols, surfactants, and silicon oil disclosed in Japanese Patent O.P.I. Publication No. 2-244143. The water softeners include polyphosphoric acid or its sodium, potassium or ammonium salt; aminopolycarboxylic acids or their salts such as ethylenediaminetetraacetic acid or its sodium, potassium or ammonium salt, diethylenetriaminepentaacetic acid or its sodium, potassium or ammonium salt, triethylenetetramine-hexaacetic acid or its sodium, potassium or ammonium salt, hydroxyethylethylene-diaminetriacetic acid or its sodium, potassium or ammonium salt, nitrilotriacetic acid or its sodium, potassium or ammonium salt, 1,2-diaminocyclohexane-tetraacetic acid or its sodium, potassium or ammonium salt, 1,3-diamino-2-propanoltetraacetic acid or its sodium, potassium or ammonium salt; and phosphonic acids or their salts such as aminotri(methylenephosphonic acid) or its sodium, potassium or ammonium salt, ethylenediaminetetra-(methylenephosphonic acid) or its sodium, potassium or ammonium salt, diethylenetriaminepenta(methylenephosphonic acid) or its sodium, potassium or ammonium salt, triethylenetetraminehexa(methylenephosphonic acid) or its sodium, potassium or ammonium salt, hydroxyethyl-ethylenediaminetri(methylenephosphonic acid) or its sodium, potassium or ammonium salt, and 1-hydroxyethane-1,1-diphosphonic acid or its sodium, potassium or ammonium salt.

The water softener content of the developer varies on hardness or amount of a hard water used, but the content is preferably 0.01 to 5 weight %, and more preferably 0.01 to 0.5 weight %. The content less than the above range cannot attain the desired objects while the content exceeding the above range has an adverse effect on image areas such as dye elimination.

### (Automatic Developing Machine)

It is advantageous that an automatic developing machine is used in order to develop a light sensitive planographic printing plate material. It is preferred that the automatic developing machine is equipped with a means for replenishing a developer replenisher in a necessary amount, a means for discharging any excessive developer and a means for automatically replenishing water in necessary amounts which is attached to the development section. It is preferred that the automatic developing machine comprises a means for detecting a transported planographic printing plate material, a means for calculating the area of the planographic printing plate material based on the detection, or a means for controlling the replenishing amount of a developer replenisher, the replenishing amount of water to be replenished, or the replenishing timing. It is also preferred that the automatic developing machine comprises a means for detecting a pH, temperature and/or electric conductivity of a developer, or a means for controlling the replenishing amount of the developer replenisher, the replenishing amount of water to be replenished or the replenishing timing, based on the detection. It is also preferred to provide a mechanism of diluting the developer concentrate with water and of stirring the diluted concentrate. Where the developing step is followed by a washing step, washing water used for washing can be reused as dilution water for diluting the developer concentrate.

The automatic developing machine used in the invention may be provided with a pre-processing section to allow the plate to be immersed in a pre-processing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

The developed planographic printing plate material is ordinarily subjected to post-processing as described later, whereby a planographic printing plate is obtained.

### (Post-Processing)

The developed printing plate material is subjected to post-processing in which the developed printing plate material is post-processed with a post-processing solution such as washing water, a rinsing solution containing a surfactant, a finisher or a protective gumming solution containing gum arabic or starch derivatives as a main component. The post-processing is carried out employing an appropriate combination of the post-processing solution described above. For example, a method is preferred in which a developed planographic printing plate material is post-washed with washing water, and then processed with a rinsing solution containing a surfactant, or a developed planographic printing plate material is post-washed with washing water, and then processed with a finisher, since it reduces fatigue of the rinsing solution or the finisher. It is preferred that a multi-step countercurrent processing is carried out employing a rinsing solution or a finisher.

The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate material to wash the plate material, and reuses the water used for washing as dilution water for developer concentrate. In the automatic developing machine, a method is applied in which each processing solution is replenished with the respective processing replenisher according to the area of the printing plate material to have been processed or the operating time of the machine. A method (use-and-discard method) can be applied in which the developed printing plate material is processed with fresh processing solution and discarded. The thus obtained planographic printing plate is mounted on a printing press, and printing is carried out.

### (Gum Solution)

Gum solution may be suitably added with acids or buffers to remove from the developed plate alkaline ingredients which are contained in the developer. Further, there may be added a hydrophilic polymer compound, a chelating agent, a lubricant, an antiseptic and a solubilizing agent. Inclusion of the hydrophilic polymer compound in the gum solution provides a function as a protecting agent to prevent the developed plate from flawing or staining.

Addition of a surfactant to the gum solution used in this invention improves the surface form of the coated layer. As the surfactant, an anionic surfactant and/or a nonionic surfactant can be used. Examples of the anionic surfactant include fatty acid salts, abietic acid salts, hydroxyalkanesulfonic acid salts, alkanesulfonic acid salts, dialkylsulfosuccinic acid salts, straight chain alkylbebzenesulfonic acid salts, branched alktlbebzenesulfonic acid salts, alkylnaphthalenesulfonic acid salts, alkylphenoxypolyoxyethylene propylsulfonic acid salts, polyoxyethylene alkylsulfophenyl ether, polyoxyethylene aryl ether sulfonic acid salts, polyoxyethylene-naphthyl ether sulfonic acid salts, N-metyl-N-oleyltaurine sodium salts, petroleum sulfonic acid salts, nitrated castor oil, sulfated tallow oil, fatty acid alkyl ester sulfuric acid ester salts, alkylnitrates, polyoxyethylene alkyl ether sulfuric acid ester salts, fatty acid monoglyceride sulfate ester salts, polyoxyethylene alkylphenyl ether sulfuric acid salts, alkylphosphate ester salts, polyoxyethylene alkyl ether phosphoric acid ester salts, polyoxyethylene alkylphenyl ether phosphoric acid ester salts, partially saponified styrene anhydrous maleic acid copolymer, partially saponified olefin-anhydrous maleic acid copolymer, and naphthalenesulfonic acid salt-formaline condensates. Of the foregoing, dialkylsulfosuccinic acid salts, alkylsulfates and alkylnaphthalenesulfonic acid salts are preferred.

Examples of the nonionic surfactant include polyoxyethylene alkyl ethers, polyoxyethylene alkylphenyl ethers, polyoxyethylene-polyoxypropylene block polymers, polyoxyethylene aryl ethers, polyoxyethylene naphthyl ethers, polyoxyethylene polystyrylphenyl ethers, polyoxyethylene polyoxypropylene alkyl ethers, glycerin fatty acid partial esters, sorbitan fatty acid partial esters, pentaerythritol fatyy acid partial esters, propylene glycol monofatty acid esters, sugar fatty acid partial esters, polyoxuethylen sorbitan fatty acid partial esters, polyoxyethylene sorbitol fatty acid partial esters, polyethylene glycol fatty acid partial esters, polyglycerin fatty acid partial esters, polyoxyethylene-modified caster oils, polyoxyethylene grycerin fatty acid partial esters, fatty acid diethanolamides, N,N-bis-2-hydroxyalkylamines, polyoxyethylene alkylamine, triethanolamine fatty acid esters and trialkylamineoxides. Of the foregoing, polyoxyethylene alkylphenyl ethers and polyoxyethylene-polyoxypropylene block polymers are preferred. There are also usable fluorinated or silicone-type anionic or nonionic surfactants. The surfactants may be used as a mixture of two or more kinds thereof. For example, a combination of at least two different anionic surfactants or a combination of at least one anionic surfactant and at least one nonionic surfactant is preferred.

The surfactant content of the gum solution is not specifically limited, but is preferably 0.01 to 20% by weight of post-processing solution.

In addition to the above ingredients, the gum solution used in the invention may contain polyhydric alcohols, alcohols or aliphatic hydrocarbons, as a wetting agent. Preferred examples of the polyhydric alcohols include ethylene glycol diethylene glycol, triethylene glycol, propylene glycol, tetraethylene glycol, polyethylene glycol, glycerin, and sorbitol. Preferred alcohols include, for example, alkyl alcohols such as propyl alcohol, butyl alcohol, pentanol, hexanol, butanol, and octanol; and alcohols containing an aromatic ring, such as benzyl alcohol, phenoxyethanol, and phenylaminoethyl alcohol.

Such a wetting agent is contained in the composition preferably at 0.1 to 50%, and more preferably 0.5 to 3.0% by weight. The wetting agents may be used alone or as a mixture of two or more kinds thereof.

There may be contained a variety of hydrophilic polymers for the purpose of enhancing film-forming ability. Any hydrophilic polymer which has been usable in a conventional gum solution is suitably usable. Examples thereof include gum Arabic, cellulose derivatives (e.g., carboxymethyl cellulose, carboxymethyl cellulose, methyl cellulose) and their modified compounds, polyvinyl alcohol and its derivatives, polyvinyl pyrrolidone, polyacrylamide and its copolymers, poly[(vinyl methyl ether)-co-(anhydrous maleic acid)], poly[(vinyl acetate)-co-(anhydrous maleic acid)], and poly[styrene-co-(anhydrous maleic acid)].

The gum solution in the invention is advantageously used within the acidic range of a pH of 3 to 6. Mineral acids, organic acids or inorganic salts are added to the post-processing solution to adjust the pH to the range of 3 to 6, preferably in an amount of 0.01 to 2% by weight. Mineral acids include, for example, nitric acid, sulfuric acid, phosphoric acid and metaphosphoric acid. Organic acids include, for example, citric acid, acetic acid, oxalic acid, malonic acid, p-toluenesulfonic acid, tartaric acid, malic acid, lactic acid, levulinic acid, phytic acid and organic phosphonic acid. Inorganic salts include, for example, magnesium nitrate, primary phosphate, secondary phosphate, nickel sulfate, sodium hexamethanate, and sodium tripolyphosphate. Mineral acids, organic acids and inorganic salts may be used alone or as a mixture of two or more kinds thereof.

The gum solution may be added with antiseptics or defoaming agents. Examples of the antiseptics include phenol and its derivatives, formaline, imidazole derivatives, sodium dehydroacetate, 4-isothiazoline-3-one derivatives, benzoisothiazoline-3-one, benzotriazole derivatives, amidinoguanine derivatives, quaternary ammonium salts, derivatives of pyridine, quinoline and guanine, diazine, triazole derivatives, oxazole, and oxazine derivatives.

A preferred content thereof is a quantity capable of taking stable effect upon bacteria, mold or yeast, depending on the kind of bacteria, molds or yeast. The content is preferably 0.01 to 4% by weight, based on the working gum solution. Two or more antiseptic are preferably used as a mixture of two or more kinds thereof to take effects upon various kinds of bacteria or molds.

Silicone defoaming agents are preferred, and any one of emulsion type and solubilization type is usable. A defoaming agent is used suitably at 0.01 to 1.0% by weight, based on the gum solution used.

Further, there may be added chelating agents. Preferred chelating agents include, for example, ethylenediaminetetraacetic acid and its sodium and potassium salts, diethylenetriaminepentaacetic acid and its sodium and potassium salts, triethylenetetraminehexaacetic acid and its sodium and potassium salts, ethylenediaminedisuccinic acid and its sodium and potassium salts, hydroxyethylethylenediaminetriacetic acid and its sodium and potassium salts, nitrilotriacetic acid and its sodium and potassium salts, and organic phosphonic acids or phosphonoalkanecarboxylic acids, such as 1-hydroxyethane-1,1-diphosphonic acid and its sodium and potassium salts, aminotri(methylenephosphonic acid) and its sodium and potassium salts. Besides the foregoing sodium and potassium salts of chelating agents, organic amine salts are also effective. Chelating agents are selected from those which can be stably present in the gum solution composition and is free from adverse effects on printing. The content thereof is preferably 0.001 to 1.0% by weight, based on the gum solution used.

In addition to the above ingredients, a lipophilicity-enhancing agent may be incorporated. Examples thereof include hydrocarbons such as turpentine oil, xylene, toluene, low heptane, solvent naphtha, kerosene, mineral spirit, petroleum fractions exhibiting a boiling point of ca. 120 to 250° C.; and plasticizers exhibiting a freezing point of 15° C. or less and a boiling point of 300° C. or more at 1 atmospheric pressure, including phthalic acid diesters such as dibutyl phthalate, diheptyl phthalate, di-n-octyl phthalate, di(2-ethylhexyl)phthalate, dinonyl phthalate, dodecyl vdilauryl phthalate, and butylbenzyl phthalate; dibasic fatty acid esters, such as dioctyl adipate, butylglycol adipate, dioctyl azelate, dibutyl sebacate, di(2-ethylhexyl)sebacate, and diocyl sebacate; epoxy-modified triglycerides such as epoxy-modified soybean oil; phosphoric acid esters such as tricresyl phosphate, trioctyl phosphate, and triscrolethyl phosphate; and benzoic acid esters such as benzyl benzoate.

Further, there are included saturated fatty acids such as caproic acid, enatoic acid, heralgonic acid, capric acid, undecylic acid, lauric acid, tridecylic acid, myristic acid, pentadecylic acid, palmitic acid, heptadecylic acid, stearic acid, nonadecanoic acid, arachic acid, behenic acid, lignoceric acid, cerotic acid, heptacosanoic acid, montanic acid, melissic acid, lacceric acid, and iso-valeric acid; and unsaturated fatty acids such as acrylic acid, crotonic acid, isocrotonic acid, undecylenic acidpleic acid, elaidic acid, cetoleic acid, nilcaic acid, btecidinic acid, sorbic acid, linolic acid, linolenic acid, arachidonic acid, propiolic acid, stearolic acid, sardine oil, tariric acid, and licanic acid. Of the foregoing, a fatty acid which is liquid at 50° C. is more preferred, one having 5 to 25 carbons is still more preferred, and one having 8 to 21 carbons is most preferred. These lipophilicity-enhancing agents may be used alone or as a mixture of two or more kinds thereof. The content thereof is preferably 0.01 to 10%, and more preferably 0.05 to 5% by weight, based on the gum solution.

The lipophilicity-enhancing agents may be incorporated through solution in the oil phase of a gum emulsion. Alternatively, they may be solubilized with the aid of a solubilizing agent.

The solid concentration of the gum solution usable in this invention is preferably 5 to 30 g/l. A gum layer thickness can be controlled by conditions of a squeezing means of a processor. The gum coverage is preferably 1 to 10 g/m². The gum coverage of more than 10 g/m² necessitates drying the plate surface at a relatively high temperature to complete drying for a short period, which is disadvantageous in terms of cost and safety, and whereby effects of this invention cannot be sufficiently achieved. A gum coverage of less than 1 g/m² results in non-uniform coating and unstable processability.

In the invention, the time from completion of coating the gum solution to start of drying is preferably 3 sec. or less, and more preferably 2 sec. or less. The shorter time enhances ink affinity. The drying time is preferably 1 to 5 sec. Effects of this invention cannot be achieved at a drying time of more than 5 sec. A drying time of less than 1 sec. necessitates raising the plate surface temperature to sufficiently dry the lithographic printing plate, leading to disadvantages in cost and safety.

Known drying methods using a hot air heater or a far-infrared heater are applicable in this invention. In the drying stage, solvents included in the gum solution need to be dried, necessitating securing sufficient drying temperature and heater capacity. The temperature needed for drying depends on the composition of the gum solution. In the case of the solvent of the gum solution being water, for example, the drying time is preferably 55° C. or more. The capacity is preferably at least 2.6 kW in a hot air drying system. A larger capacity is desirable and a capacity of 2.6 to 7 kW is preferred in balance with cost.

### (Washing Water Used Prior to Development)

Washing solution used in the washing stage prior to development invention is usually common water and may optionally be added with the following additives.

Chelating agents are used which are capable of coordination-bonding with a metal ion to form a chelate compound. Examples of the chelating agents include ethylenediaminetetraacetic acid and its potassium and sodium salts, ethylenediaminedisuccinic acid and its potassium and sodium salts, triethylenetetraminehexaacetic acid and its sodium and potassium salts, diethylenetriaminepentaacetic acid and its sodium and potassium salts, hydroxyethylethyl-enediaminetriacetic acid and its sodium and potassium salts, nitrilotriacetic acid and its sodium and potassium salts, 1-hydroxyethane-1,1-diphosphonic acid and its sodium and potassium salts, aminotri(methylenephosphonic acid) and its sodium and potassium salts and phosphonoalkanetricarboxylic acid. Besides the sodium and potassium salts of chelating agents, their organic amine salts are also effective. These chelating agents are contained in an amount of 0 to 3.0% by weight.

Surfactants usable in the invention include any one of anionic, nonionic, cationic and amphoteric surfactants, and anionic and nonionic surfactants are preferably used. The kind of preferred surfactants is different depending on the composition of an over-coat layer or photosensitive layer. In general are preferred surfactants which are capable of promoting dissolution of material used in the over-coat layer and exhibit less solubility for components of the photosensitive layer. Examples of the anionic surfactants include fatty acid salts, abietic acid salts, hydroxyalkanesulfonates, alkanesulfonates, dialkylsulfosuccinates, straight chain alkylbebzenesulfonates, branched alktlbebzenesulfonates, alkylnaphthalenesulfonates, alkylphenoxypolyoxyethylene propylsulfonates, polyoxyethylene alkylsulfophenyl ether, polyoxyethylene aryl ether sulfonic acid salts, polyoxyethylene-naphthyl ether sulfonic acid salts, N-metyl-N-oleyltaurine sodium salts, petroleum sulfonic acid salts, nitrated castor oil, sulfated tallow oil, fatty acid alkyl ester sulfuric acid ester salts, alkylnitrates, polyoxyethylene alkyl ether sulfuric acid ester salts, fatty acid monoglyceride sulfate ester salts, polyoxyethylene alkylphenyl ether sulfuric acid salts, alkylphosphate ester salts, polyoxyethylene alkyl ether phosphoric acid ester salts, polyoxyethylene alkylphenyl ether phosphoric acid ester salts, partially saponified styrene anhydrous maleic acid copolymer, partially saponified olefin-anhydrous maleic acid copolymer, and naphthalenesulfonate formaline condensates. Of the foregoing, dialkylsulfosuccinates, alkylsulfates and alkylnaphthalenesulfonates are preferred. Examples of the nonionic surfactants include polyoxyethylene alkyl ethers, polyoxyethylene alkylphenyl ethers, polyoxyethylene-polyoxypropylene block polymers, polyoxyethylene aryl ethers, polyoxyethylene naphthyl ethers, polyoxyethylene polystyrylphenyl ethers, polyoxyethylene polyoxypropylene alkyl ethers, glycerin fatty acid partial esters, sorbitan fatty acid partial esters, pentaerythritol fatyy acid partial esters, propylene glycol monofatty acid esters, sugar fatty acid partial esters, polyoxuethylen sorbitan fatty acid partial esters, polyoxyethylene sorbitol fatty acid partial esters, polyethylene glycol fatty acid partial esters, polyglycerin fatty acid partial esters, polyoxyethylene-modified caster oils, polyoxyethylene grycerin fatty acid partial esters, fatty acid diethanolamides, N,N-bis-2-hydroxyalkylamines, polyoxyethylene alkylamine, triethanolamine fatty acid esters and trialkylamineoxides. The surfactant is contained preferably in an amount of 0 to 10% by weight. The surfactant may be used in combination with defoaming agents.

Antiseptics usable in the invention include, for example, phenol and its derivatives, formaline, imidazole derivatives, sodium dehydroacetate, 4-isothiazoline-3-one derivatives, benzoisothiazoline-3-one, benzotriazole derivatives, amidinoguanine derivatives, quaternary ammonium salts, derivatives of pyridine, quinoline and guanine, diazine, triazole derivatives, oxazole, and oxazine derivatives.

In washing, a washing solution used prior to development is used preferably at a controlled temperature, and more preferably at 10 to 60° C. Washing can be performed using commonly known solution-feeding techniques such as a spraying, dipping or coating method. During washing, a wash promoting method employing a brush, a squeezing roll or a submerged shower in a dipping treatment can be suitably used.

After completion of the washing stage prior to development, development may be immediately conducted, or drying may be conducted after the washing stage, subsequently, development may be performed. The development stage is followed by a post-treatment such as washing, rinsing or a gumming treatment. Washing water used prior to development may also be reused as washing water or for a rinsing solution or gumming solution.

The light sensitive planographic printing plate material in the invention comprises an aluminum support and provided thereon, a light sensitive layer containing an ethylenically unsaturated compound, a photopolymerization initiator, and a polymeric binder.

Components used in the light sensitive layer of the light sensitive planographic printing plate material of the invention will be explained.

### (Addition Polymerizable Ethylenically Unsaturated Compound)

The addition polymerizable ethylenically unsaturated compound (hereinafter also referred to as ethylenically unsaturated compound) is a compound having an ethylenic double bond capable of polymerizing on exposure. As the addition polymerizable ethylenically unsaturated compound in the invention, there are a known monomer such as a radical polymerizable monomer, and a polyfunctional monomer or oligomer having two or more of an ethylenic double bond in the molecule generally used in an ultraviolet curable resin composition. The monomers are not specifically limited.

Preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryl-oxyethyl acrylate, tetrahydrofurfuryloxyhexanorideacrylate, an ester of 1,3-dioxane-ε-caprolactone adduct with acrylic acid, or 1,3-dioxolane acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate or hydroxypivalylaldehyde modified dimethylolpropane triacrylate; a methacrylate, itaconate, crotonate or maleate alternative of the above polyfunctional acrylate.

A prepolymer can be used, and examples of the prepolymer include compounds as described later. The prepolymer with a photopolymerizable property, which is obtained by incorporating acrylic acid or methacrylic in an oligomer with an appropriate molecular weight, can be suitably employed. These prepolymers can be used singly, in combination or as their mixture with the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate, hydroxyethylphthalyl methacrylate.xylenediisocyanate, 1,2-polybutadieneglycol.tolylenediisocyanate.2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

Further, as the ethylenically unsaturated compound, there are a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, and an addition polymerizable oligomer or prepolymer having a structural unit derived from the above monomer.

Furthermore, there is a phosphate compound having at least one (meth)acryloyl group. The phosphate compound is a compound having a (meth)acryloyl group in which at least one hydroxyl group of phosphoric acid is esterified, and the phosphate compound is not limited as long as it has a (meth)acryloyl group.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV-EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

In the invention, an ethylenically unsaturated compound (a tertiary amine) having a tertiary amino group in the molecule is preferably used. Its molecular structure is not limited, but those are preferred in which a tertiary amine having a hydroxyl group is modified with glycidyl methacrylate, methacrylic chloride, or acrylic chloride. Examples thereof include a polymerizable compound disclosed I Japanese Patent O.P.I. Publication Nos. 1-165613, 1-203413 and 1-197213.

A reaction product of a polyhydric alcohol having a tertiary amino group in the molecule, a diisocyanate and a compound having a hydroxyl group and an addition polymerizable ethylenically double bond in the molecule is preferably used in the invention. can be synthesized according to the same method as a conventional method in which a urethaneacrylate compound is ordinarily synthesized employing a diol, a diisocyanate and an acrylate having a hydroxyl group.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N,N′,N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Examples of the compound having a hydroxyl group and an addition polymerizable ethylenically double bond in the molecule include the following compounds MH-1 through MH-13, but the invention is not specifically limited thereto.

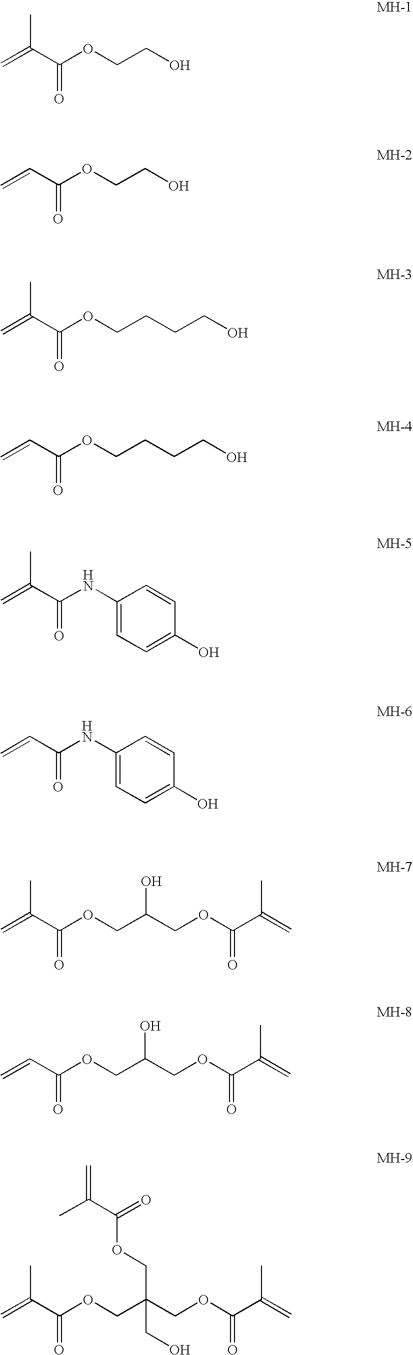

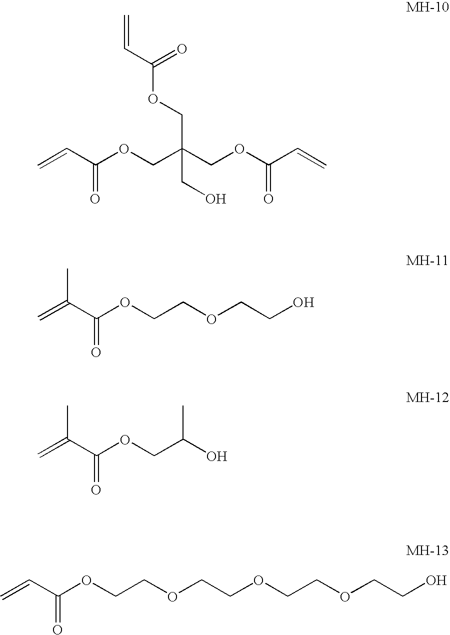

Preferred examples thereof include 2-hydroxyethyl methacrylate (MH-1), 2-hydroxyethyl acrylate (MH-2), 4-hydroxybutyl acrylate (MH-4), 2-hydroxypropylene-1,3-dimethacrylate (MH-7), and 2-hydroxypropylene-1-methacrylate-3-acrylate (MH-8).

The reaction product above can be synthesized according to the same method as a conventional method in which a urethaneacrylate compound is ordinarily synthesized employing an ordinary diol, a diisocyanate and an acrylate having a hydroxyl group.

Examples of the reaction product of a polyhydric alcohol having a tertiary amino group in the molecule, a diisocyanate and a compound having a hydroxyl group and an addition polymerizable ethylenically double bond in the molecule will be listed below.
M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)

In addition to the above, acrylates or methacrylates disclosed in Japanese Patent O.P.I. Publication Nos. 1-105238 and 2-127404 can be used.

In the invention, the ethylenically unsaturated compound is preferably one represented by formula (1) or (2) disclosed in Japanese Patient O.P.I. Publication Nos. 2005-221542.

Preferred examples of the ethylenically unsaturated compound used in the invention will be listed below, but the invention is not limited thereto.

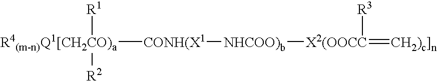

| Compound No. | R⁴ | Q¹ | m | a | R¹ | R² | b | X¹ | X² | c | R³ | n |
|---|---|---|---|---|---|---|---|---|---|---|---|---|
| 1-1 | — | 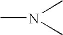 | 3 | 1 | H | H | 0 | — | C₂H₄ | 1 | CH₃ | 3 |
| 1-2 | — | 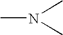 | 3 | 1 | CH₃ | H | 0 | — | C₂H₄ | 1 | CH₃ | 3 |
| 1-3 | C₂H₄OH | 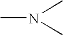 | 3 | 1 | H | H | 0 | — | C₂H₄ | 1 | CH₃ | 2 |
| 1-4 | — | 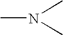 | 3 | 1 | H | H | 1 | *1 | C₂H₄ | 1 | CH₃ | 3 |
| 1-5 | — | 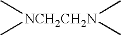 | 4 | 1 | H | H | 0 | — | C₂H₄ | 1 | CH₃ | 4 |
| 1-6 | — | 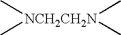 | 4 | 1 | CH₃ | H | 0 | — | C₂H₄ | 1 | CH₃ | 4 |
| 1-7 | — | 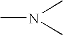 | 3 | 1 | H | H | 0 | — | C₃H₆ | 1 | CH₃ | 3 |
| 1-8 | — | 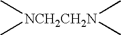 | 4 | 1 | H | H | 0 | — | C₃H₆ | 1 | CH₃ | 4 |
| 1-9 | — | 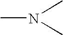 | 3 | 1 | H | H | 0 | — | C₂H₄ | 1 | H | 3 |
| 1-10 | — | 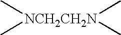 | 4 | 1 | H | H | 0 | — | C₂H₄ | 1 | H | 4 |
| 1-11 | — | —S— | 2 | 1 | H | H | 0 | — | C₂H₄ | 1 | CH₃ | 2 |

1-12

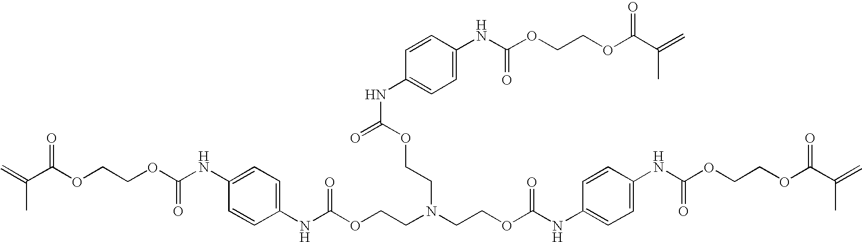

1-13

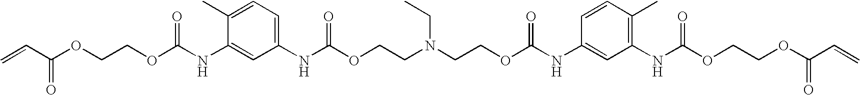

1-14

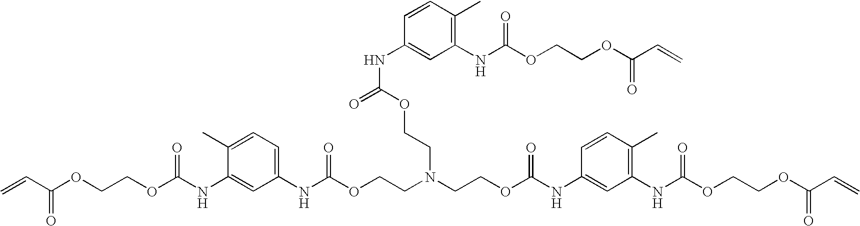

1-15

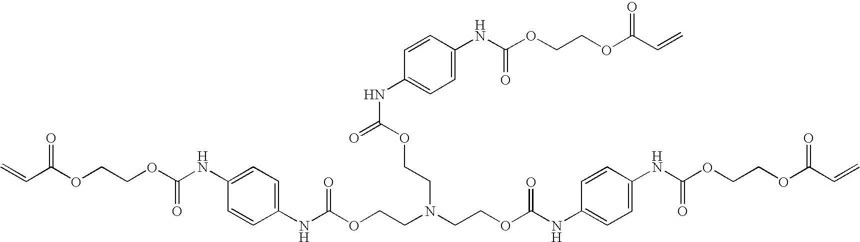

1-16

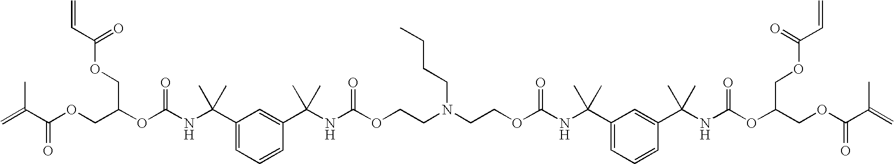

1-17

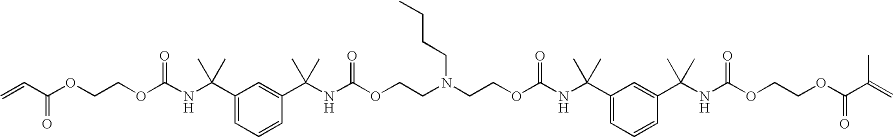

1-18

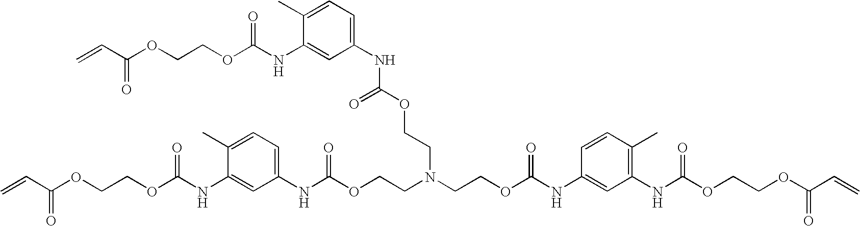

1-19

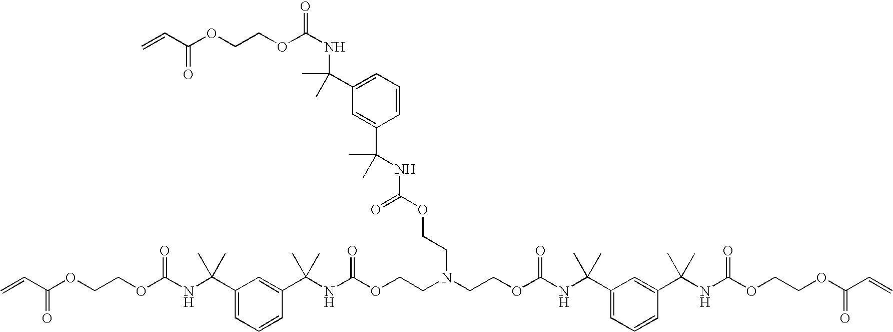

1-20

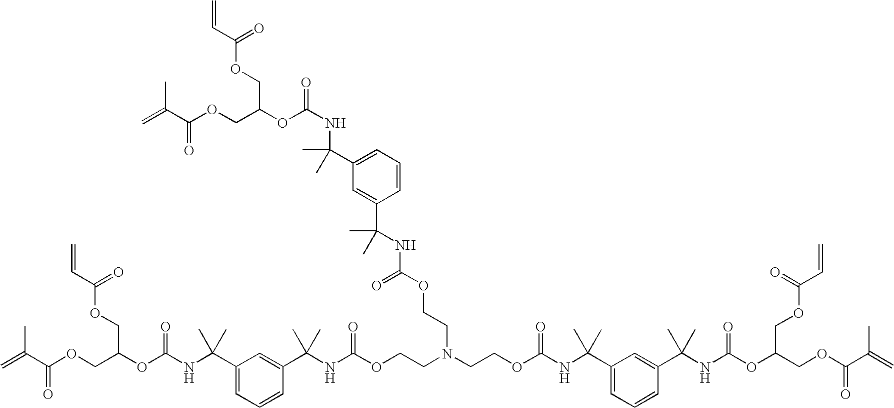

*1: 2,2,4-trimethylhexamethylene

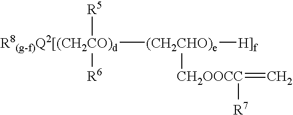

| [symbol] No. | R⁸ | Q² | g | d | R⁵ | R⁶ | e | R⁷ | f |
|---|---|---|---|---|---|---|---|---|---|
| 2-1 | — | 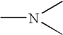 | 3 | 1 | H | H | 1 | CH₃ | 3 |
| 2-2 | — | 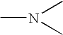 | 3 | 1 | CH₃ | H | 1 | CH₃ | 3 |
| 2-3 | CH₂CH₂OH | 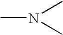 | 3 | 1 | H | H | 1 | CH₃ | 2 |
| 2-4 | — | 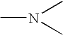 | 3 | 1 | CH₃ | H | 1 | H | 3 |
| 2-5 | — | 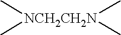 | 4 | 1 | H | H | 1 | CH₃ | 4 |
| 2-6 | — | 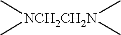 | 4 | 1 | CH₃ | H | 1 | CH₃ | 4 |
| 2-7 | C₆H₅ | 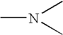 | 3 | 1 | H | H | 1 | H | 2 |
| 2-8 | — | 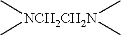 | 4 | 1 | CH₃ | H | 1 | H | 4 |
| 2-9 | — | 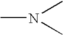 | 3 | 1 | H | H | 1 | H | 3 |
| 2-10 | — | 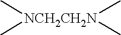 | 4 | 1 | H | H | 1 | H | 4 |
| 2-11 | — | —S— | 2 | 1 | H | H | 1 | CH₃ | 2 |
| 2-12 | — | *2 | 4 | 1 | H | H | 1 | CH₃ | 4 |

*2

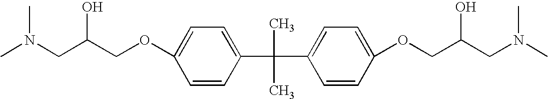

The ethylenically unsaturated compound content of the light sensitive layer is preferably form 30 to 70% by weight, and more preferably from 40 to 60% by weight.

### (Photopolymerization Initiator)

Next, a photopolymerization initiator used in the invention will be explained. As the photopolymerization initiator in the invention, there are, for example, a biimidazole compound, an iron-arene complex, and a polyhalogen compound. In the invention, the biimidazole compound or the polyhalogen compound is preferably used.

The biimidazole compound will be explained below.

The biimidazole compound is a derivative of biimidazole, and examples thereof include those disclosed in for example, Japanese Patent O.P.I. Publication No. 2003-295426.

In the invention, a hexaarylbisimidazole (HABI, a dimer of a triarylimidazole) compound is preferred as the biimidazole compound.

The synthetic method of the hexaarylbisimidazoles (HABI, dimmers of triarylimidazoles) is disclosed in DE 1470154, and use thereof in a photopolymerizable composition is disclosed in EP 24629, EP 107792, U.S. Pat. No. 4,410,621, EP 215453 and DE 321312.

Preferred examples of the biimidazole compound include 2,4,5,2′,4′,5′-hexaphenylbisimidazole, 2,2′-bis(2-chlorophenyl)-4,5,4′,5′-tetraphenylbisimidazole, 2,2′-bis(2-bromophenyl)-4,5,4′,5′-tetraphenylbisimidazole, 2,2′-bis2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,5′-tetrakis(3,4,5-trimethoxyphenyl)bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole, and 2,2′-bis(2,6-difluorophenyl)-4,5,4′,5′-tetraphenylbisimidazole.

Next, the iron arene complex used in the invention will be explained. The iron arene complex used in the invention is a compound represented by formula (a) below.

(A-Fe—B)⁺X⁻ Formula (a)

wherein A represents a substituted or unsubstituted cyclopentadienyl group or a substituted or unsubstituted cyclohexadienyl group; B represents a compound having an aromatic ring; and X⁻ is an anion.

Examples of the compound having an aromatic ring include benzene, toluene, xylene, cumene, naphthalene, 1-methylnaphtalene, 2-methylnaphtalene, biphenyl, fluorene, anthracene and pyrene. Examples of X⁻ include PF₆⁻, BF₄⁻, SbF₆⁻, AlF₄⁻, and CF₃SO₃⁻. The substituents of the substituted or unsubstituted cyclopentadienyl group or a substituted or unsubstituted cyclohexadienyl group include an alkyl group such as methyl, ethyl, etc., a cyano group, an acetyl group and a halogen atom.

Examples of the iron arene complex include:
Fe-1: (η6-benzene)(η5-cyclopentadienyl)iron (2) hexafluorophosphate;
Fe-2: (η6-toluene)(η5-cyclopentadienyl)iron (2) hexafluorophosphate;
Fe-3: (η6-cumene)(η5-cyclopentadienyl)iron (2) hexafluorophosphate;
Fe-4: (η6-benzene)(η5-cyclopentadienyl)iron (2) hexafluoroarsenate;
Fe-6: (η6-benzene)(η5-cyclopentadienyl)iron (2) tetrafluoroborate;
Fe-6: (η6-naphthalene)(η5-cyclopentadienyl)iron (2) hexafluorophosphate;
Fe-7: (η6-anthracene)(η5-cyclopentadienyl)iron (2) hexafluorophosphate;
Fe-8: (η6-pyrene)(η5-cyclopentadienyl)iron (2) hexafluorophosphate;
Fe-9: (η6-benzene)(η5-cyanocyclopentadienyl)iron (2) hexafluorophosphate;
Fe-10: (η6-toluene)(η5-acetylcyclopentadienyl)iron (2) hexafluorophosphate;
Fe-11: (η6-cumene)(η5-cyclopentadienyl)iron (2) tetrafluoroborate;
Fe-12: (η6-benzene)(η5-carboethoxycyclohexadienyl)iron (2) hexafluorophosphate;
Fe-13: (η6-benzene)(η5-1,3-dichlorocyclohexadienyl)iron (2) hexafluorophosphate;
Fe-14: (η6-cyanobenzene)(η5-cyclohexadienyl)iron (2) hexafluorophosphate;
Fe-15: (η6-acetophenone)(η5-cyclohexadienyl)iron (2) hexafluorophosphate;
Fe-16: (η6-methyl benzoate)(η5-cyclopentadienyl)iron (2) hexafluorophosphate;
Fe-17: (η6-benzene sulfonamide)(η5-cyclopentadienyl)iron (2) tetrafluoroborate;
Fe-18: (η6-benzamide)(η5-cyclopentadienyl)iron (2) hexafluorophosphate;
Fe-19: (η6-cyanobenzene)(η5-cyanocyclopentadienyl)iron (2) hexafluorophosphate;
Fe-20: (η6-chloronaphthalene)(η5-cyclopentadienyl)iron (2) hexafluorophosphate;
Fe-21: (η6-anthracene)(η5-cyanocyclopentadienyl)iron (2) hexafluorophosphate;
Fe-22: (η6-chlorobenzene)(η5-cyclopentadienyl)iron (2) hexafluorophosphate; and
Fe-23: (η6-chlorobenzene)(η5-cyclopentadienyl)iron (2) tetrafluoroborate.

These compounds can be synthesized according to a method described in Dokl. Akd. Nauk. SSSR 149 615 (1963).

Next, the polyhalogen compound will be explained. As the polyhalogen compound, a polyhalogen compound represented by formula (3), (4) and (5) is preferred.

Preferred examples of the polyhalogen compound will be listed below, but the invention is not limited thereto.

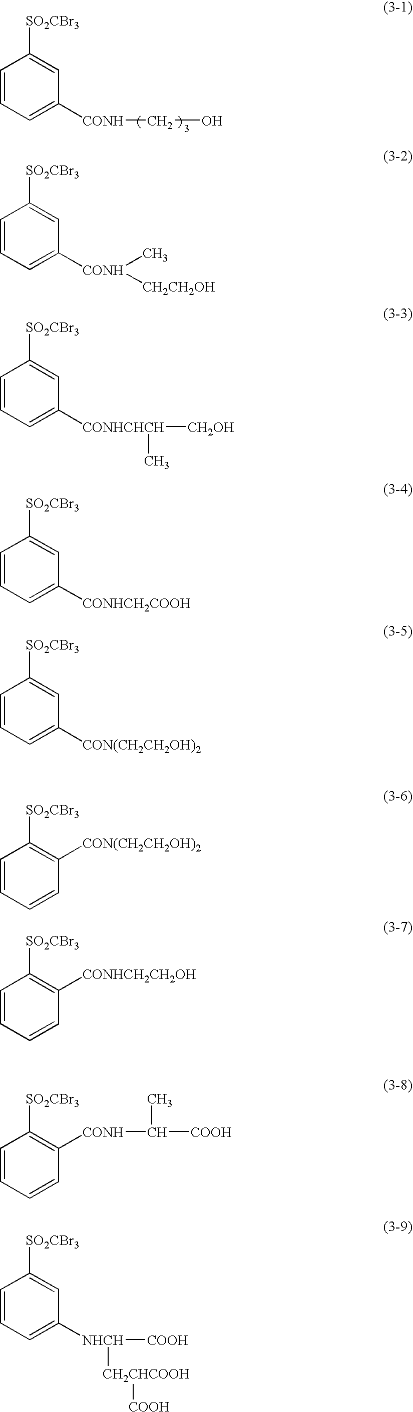

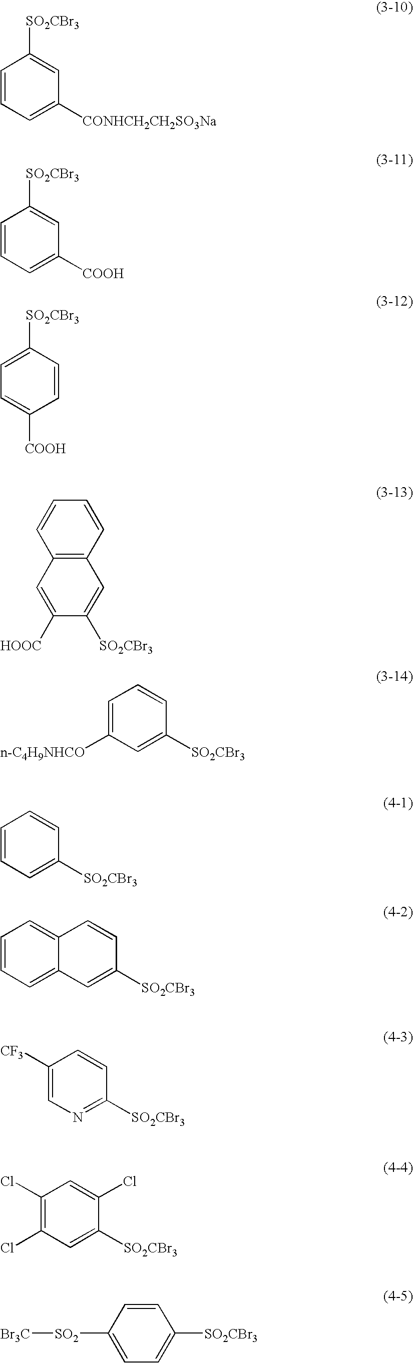

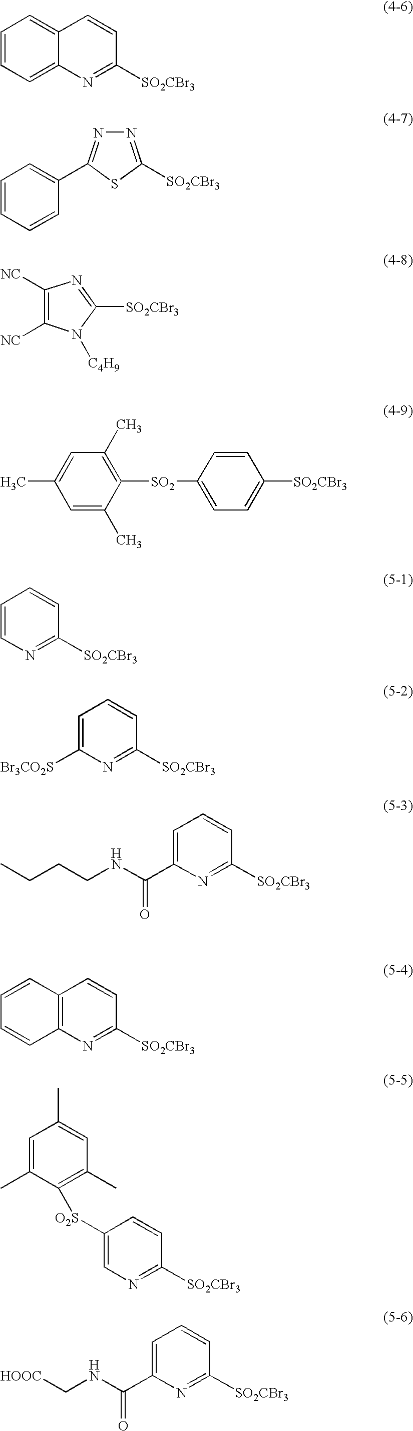

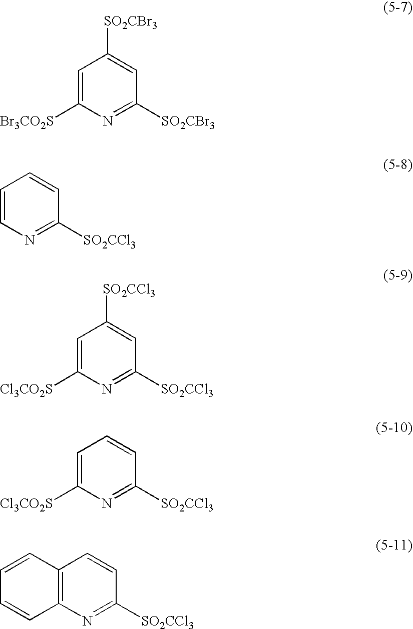

The polyhalogen compound used in the invention is preferably a polyhaloacetyl compound, and more preferably a trihaloacetylamide compound. The polyhaloacetyl compound is preferably a compound represented by the following formula (I), and more preferably a compound represented by the following formula (II).

R¹¹—C(X¹⁰)₂—(C═O)—R¹² Formula (I)

wherein X¹⁰ represents a chlorine atom or a bromine atom; R¹¹ represents a hydrogen atom, a chlorine atom, a bromine atom, an alkyl group, an aryl group, an acyl group, an alkylsulfonyl group, an arylsulfonyl group or a cyano group; R¹² represents a monovalent substituent, provided that R¹¹ and R¹² may combine with each other to form a ring.

C(X¹¹)₃—(C═O)—Y¹⁰—R¹³ Formula (II)

wherein X¹¹ represents a chlorine atom or a bromine atom; R¹³ represents a monovalent substituent; and Y¹⁰ represents —O—, or —NR¹⁴ in which R¹⁴ represents a hydrogen atom or an alkyl group, provided that R¹³ and R¹⁴ may combine with each other to form a ring.

Typical exemplified compounds (BR 1 through BR 76) of compounds represented by formula (I) are listed below, but the invention is not limited thereto.

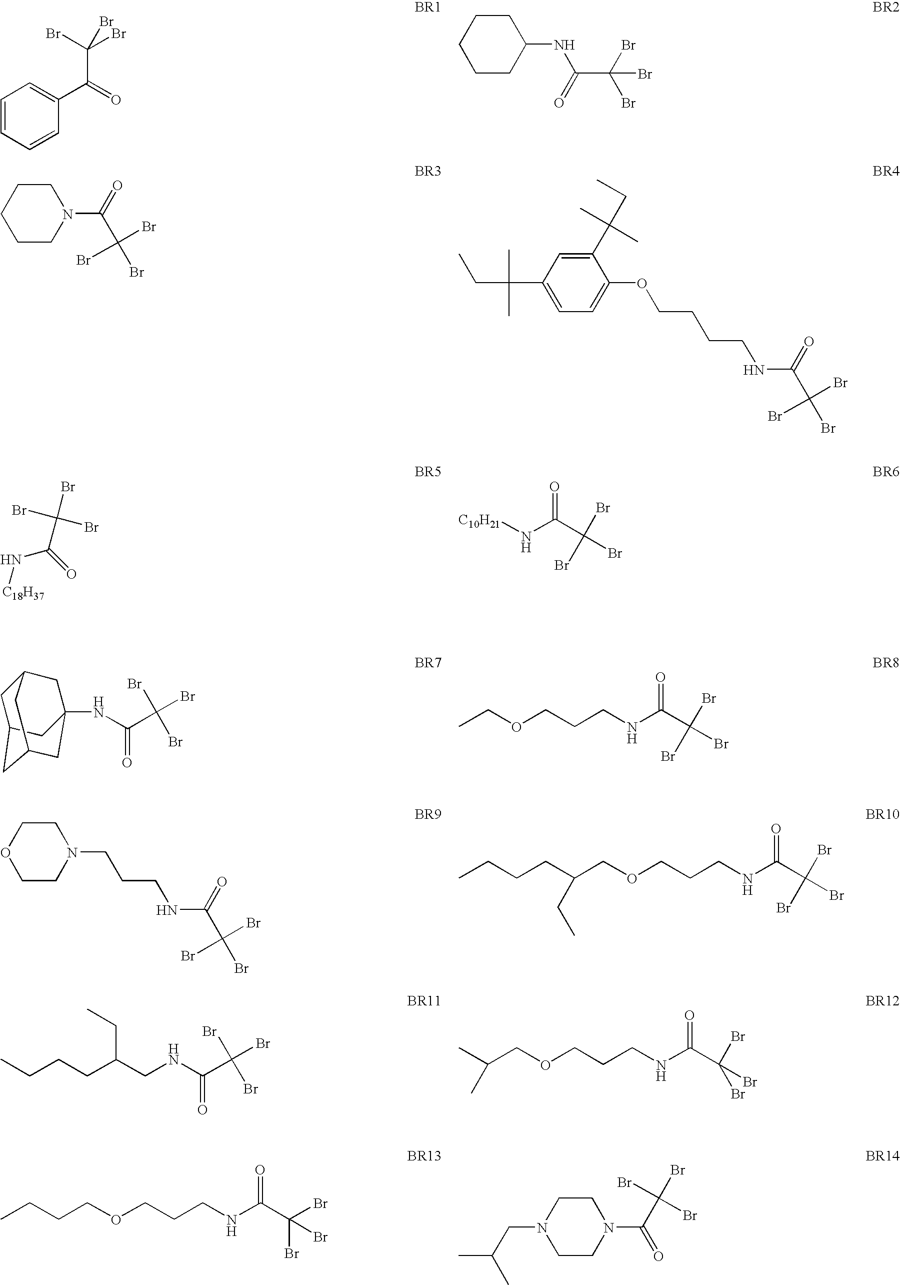

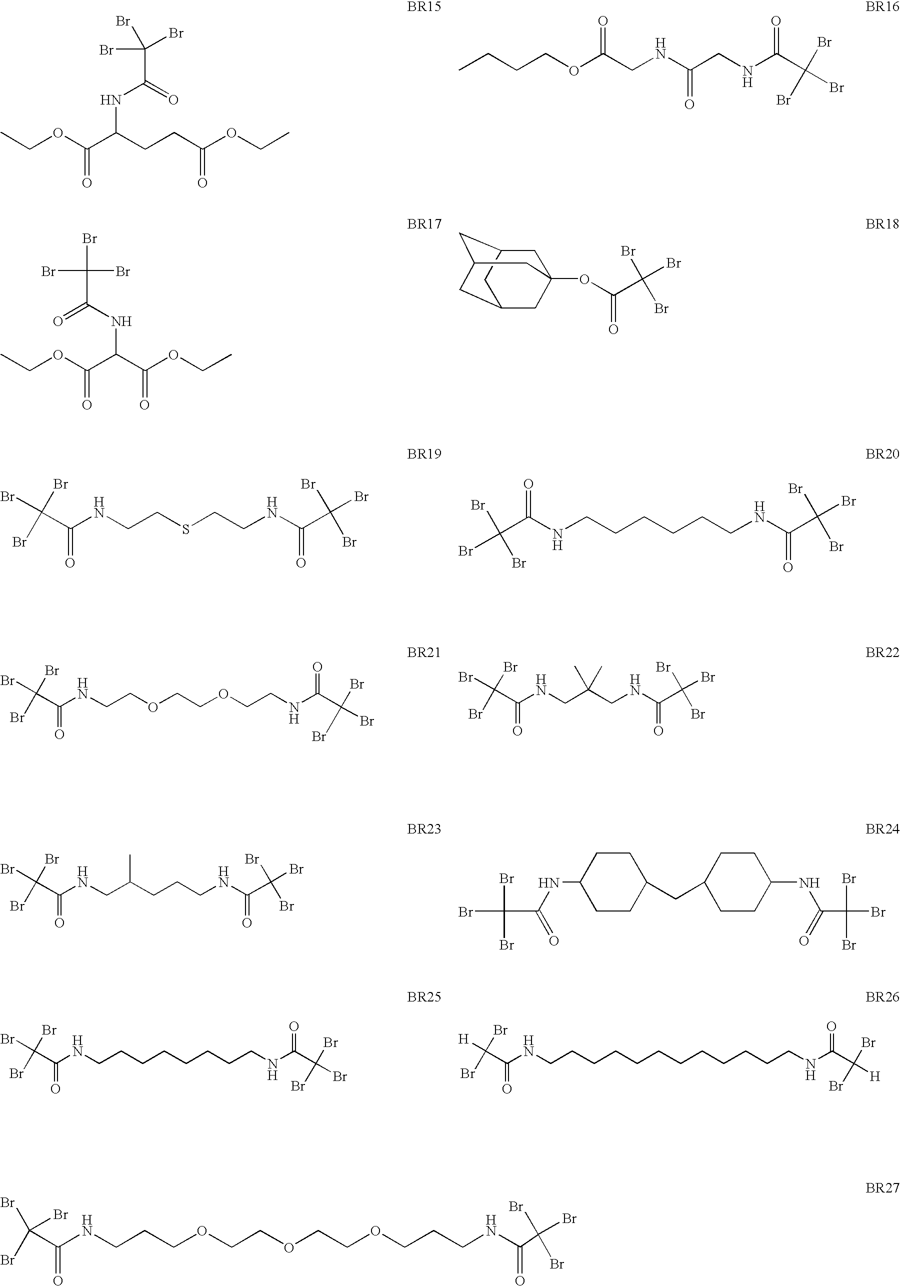

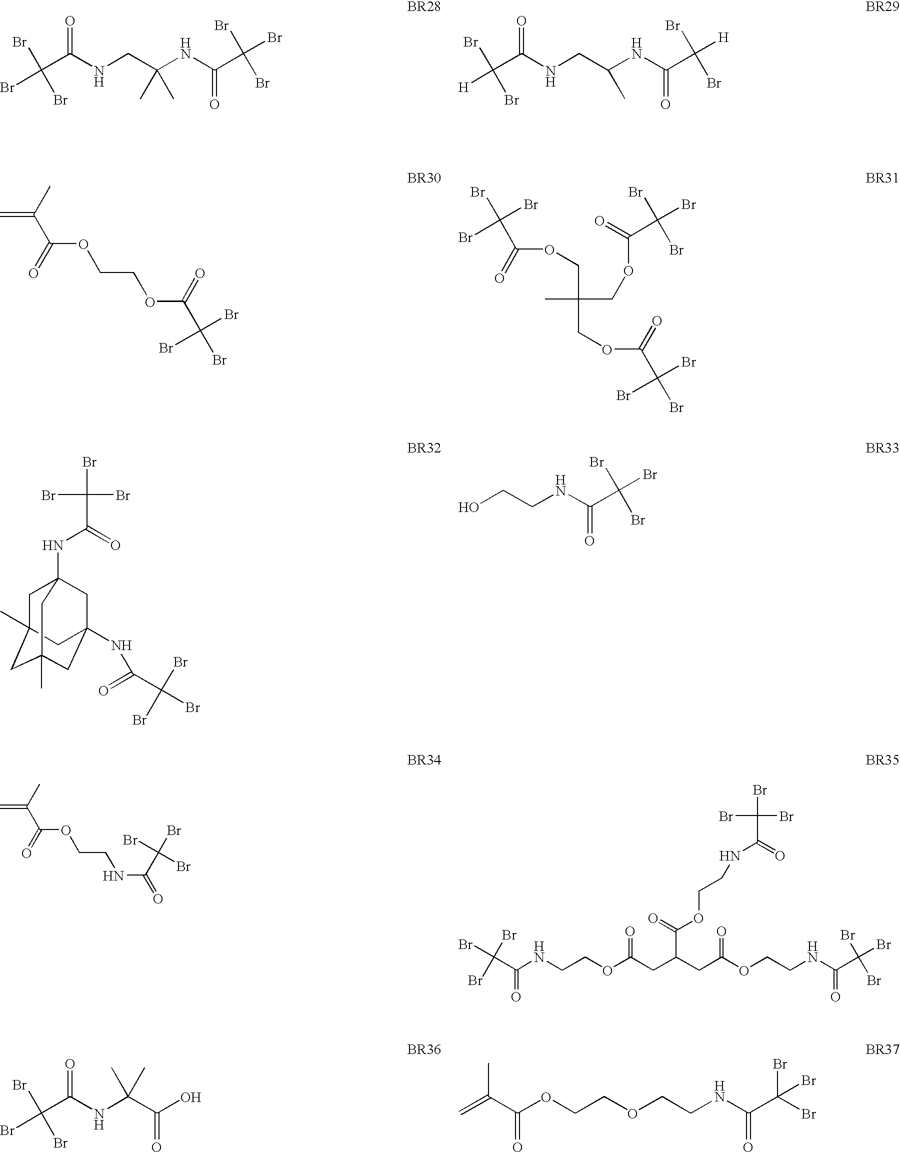

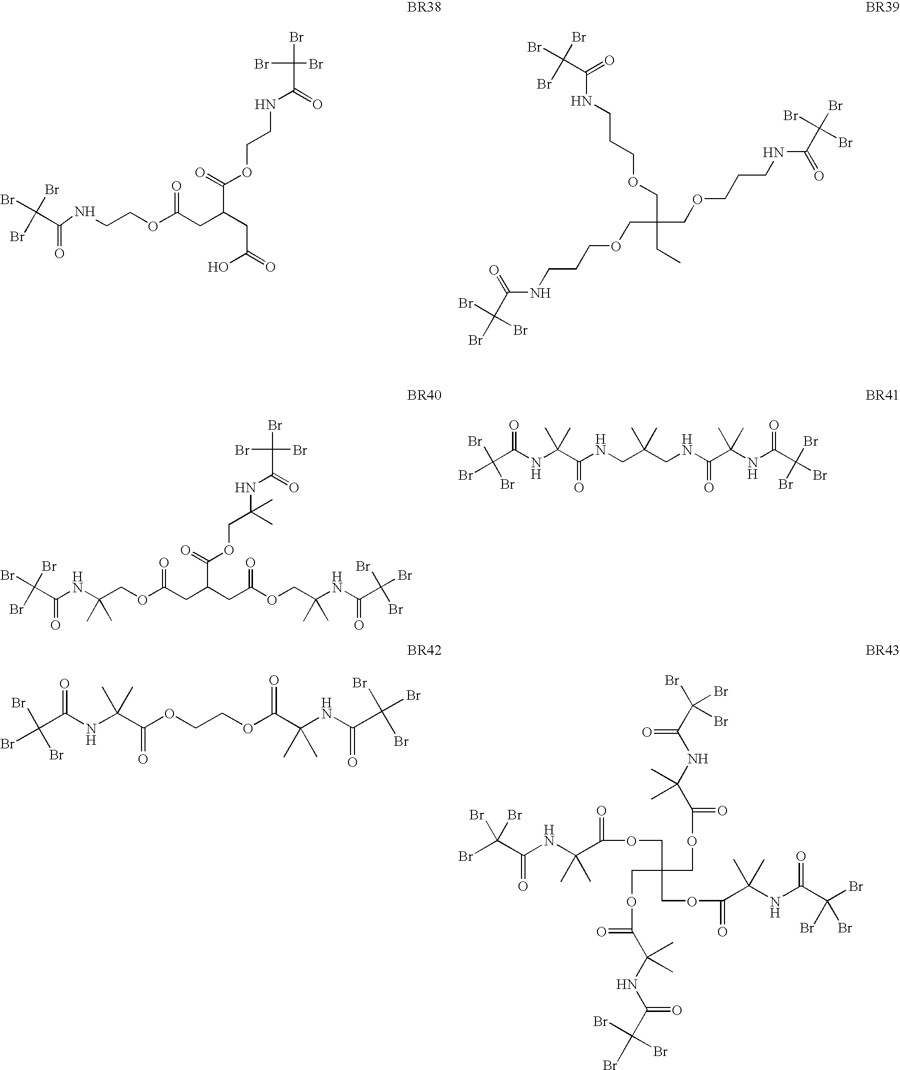

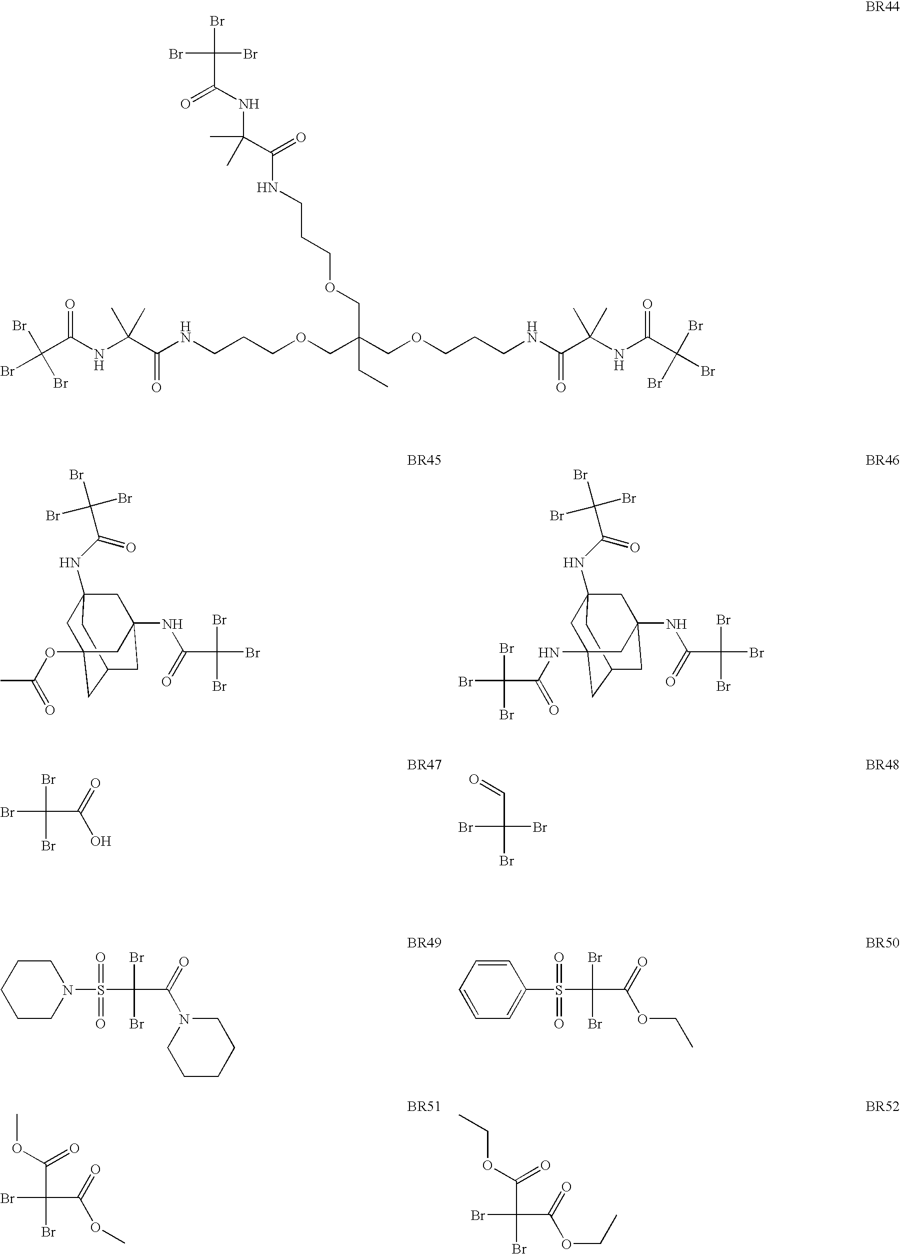

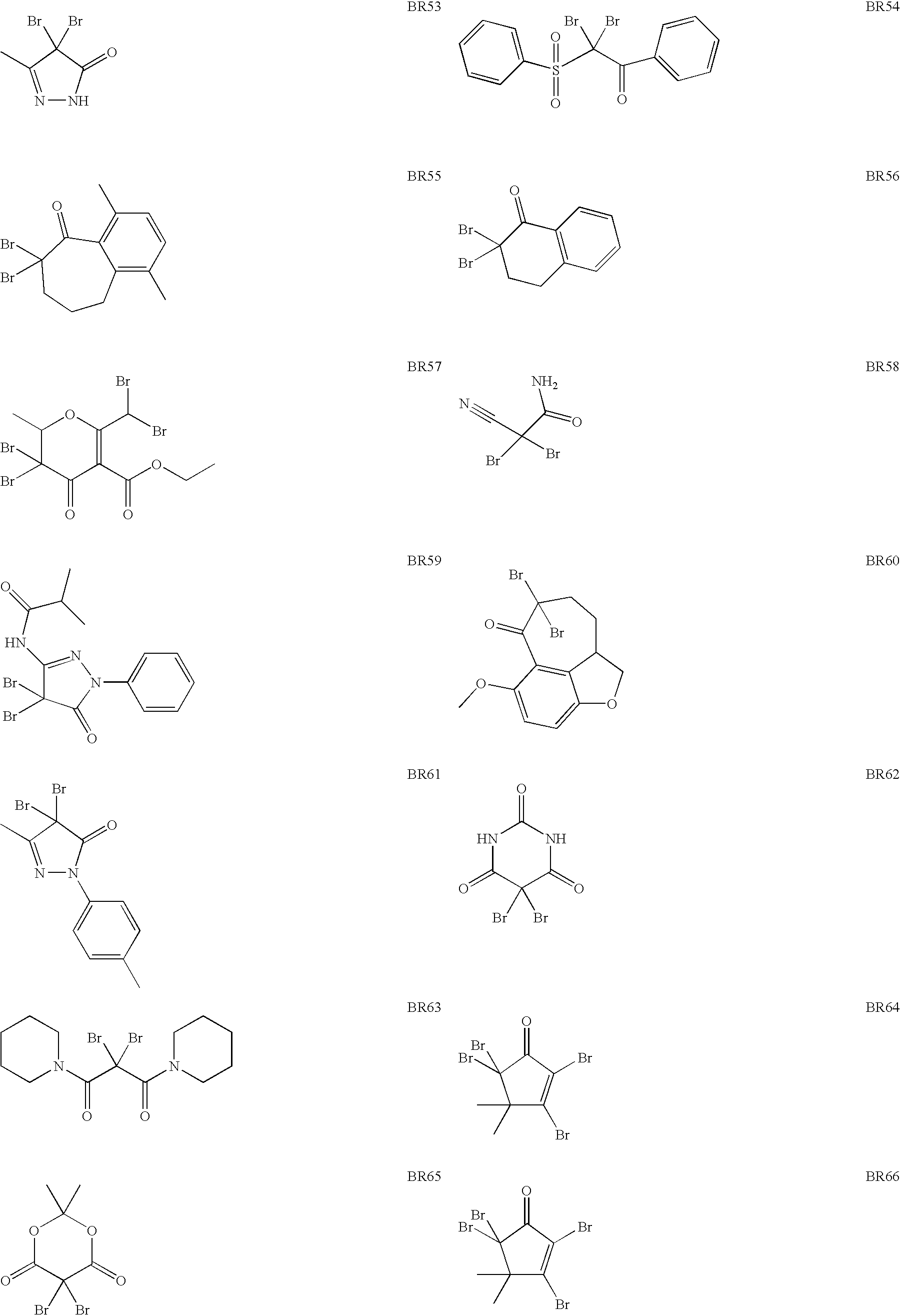

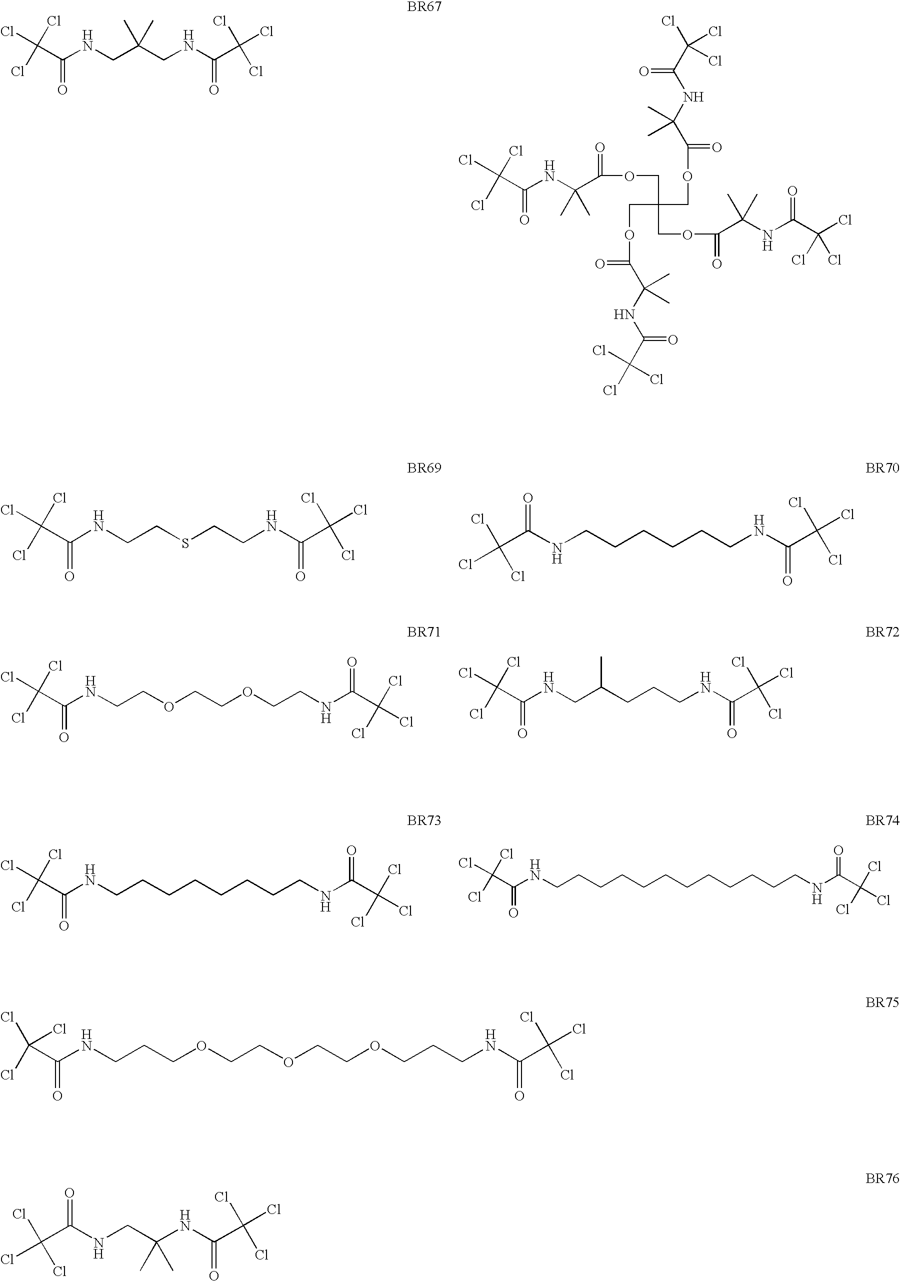

Preferred examples of compounds represented by formula (II) are compounds BR 2 through BR 47, and BR 67 through BR 76 exemplified above.

Among the polyhalogen compounds described above, polybromine compounds are preferred.

As a polyhalogen compound, a trihalomethyl triazine compound is preferably used in the invention. Listed are, for example, compounds described in Bull. Chem. Soc. Japan, 42, 2924 (1969), by Wakabayashi et. al., such as 2-phenyl-4,6-bis(trichloromethyl)-s-triazine, 2-(p-chlorophenyl)-4,6-bis(trichloromethyl)-s-triazine, 2-(p-tlyl)-4,6-bis(trichloromethyl)-s-triazine, 2-(p-methoxyphenyl)-4,6-bis(trichloromethyl)-s-triazine, 2-(2′,4′-dichlorophenyl)-4,6-bis(trichloromethyl)-s-triazine, 2,4,6-tris(trichloromethyl)-s-triazine, 2-methyl-4,6-bis(trichloromethyl)-s-triazine, 2-n-nonyl-4,6-bis(trichloromethyl)-s-triazine and 2-(α,α,β-trichloroethyl)-4,6-bis(trichloromethyl)-s-triazine. In addition to this, listed are compounds described in BP No. 1388492, for example, such as 2-styryl-4,6-bis(trichloromethyl)-s-triazine, 2-(p-methylstyryl)-4,6-bis(trichloromethyl)-s-triazine, 2-(p-methoxystyryl)-4,6-bis(trichloromethyl)-s-triazine and 2-(p-methoxystyryl)-4-amino-6-trichloromethyl-s-triazine; compounds described in JP-A No. 53-133428, for example, such as 2-(4-methoxy-naphtho-1-yl)-4,6-bis(trichloromethyl)-s-triazine, 2-(4-ethoxy-naphtho-1-yl)-4,6-bis(trichloromethyl)-s-triazine, 2-[4-(2-ethoxyethyl)-naphtho-1-yl]-4,6-bis(trichloromethyl)-s-triazine, 2-[4,7-dimethoxy-naphtho-1-yl]-4,6-bis(trichloromethyl)-s-triazine and 2-(acetonaphtho-5-yl)-4,6-bis(trichloromethyl)-s-triazine; and compounds described in German Patent No. 3337024. Further, listed are compounds described in J. Org. Chem., 29, 1527(1964) by F. C. Schaefer et. al., for example, such as 2-methyl-4,6-bis(tribromomethyl)-s-triazine, 2,4,6-tris(tribromomethyl)-s-triazine, 2,4,6-tris(dibromomethyl)-s-triazine, 2-amino-4-methyl-6-tribromomethyl-s-triazine and 2-methoxy-4-methyl-6-trichloromethyl-s-triazine.

In the invention, known photopolymerization initiator such as aromatic ketones, aromatic onium salts, organic peroxides, thio compounds, hexarylbiimidazoles, ketoxime esters, borate compounds, azinium compounds, metallocenes, active ester compounds, and compounds having a carbon-halogen bond can be used in combination as a photopolymerization initiator.

The content of the photopolymerization initiator in the light sensitive layer is preferably from 0.1 to 20% by weight, and more preferably from 0.1 to 10% by weight, based on the amount of the polymerizable ethylenically unsaturated compound contained in the light sensitive layer.

### (Polymeric Binder)

Next, the polymeric binder will be explained.

As the polymeric binder in the invention can be used a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an admixture of two or more thereof.

The polymeric binder used in the invention is preferably a vinyl copolymer obtained by copolymerization of an acryl monomer, and more preferably a copolymer containing (a) a carboxyl group-containing monomer unit and (b) an alkyl methacrylate or alkyl acrylate unit as the copolymerization component.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymeric binder in the invention can further contain, as another monomer unit, a monomer unit derived from the monomer described in the following items (1) through (14):

(1) A monomer having an aromatic hydroxy group, for example, o-, (p- or m-) hydroxystyrene, or o-, (p- or m-) hydroxyphenylacrylate;

(2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

(3) A monomer having an aminosulfonyl group, for example, m- or p-aminosulfonylphenyl methacrylate, m- or p-aminosulfonylphenyl acrylate, N-(p-aminosulfonylphenyl)methacrylamide, or N-(p-aminosulfonylphenyl)acrylamide;

(4) A monomer having a sulfonamido group, for example, N-(p-toluenesulfonyl)acrylamide, or N-(p-toluenesulfonyl)-methacrylamide;

(5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

(6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

(7) A vinyl ether, for example, ethyl vinyl ether, 2-chloroethyl vinyl ether, propyl vinyl ether, butyl vinyl ether, octyl vinyl ether, or phenyl vinyl ether;

(8) A vinyl ester, for example, vinyl acetate, vinyl chroloacetate, vinyl butyrate, or vinyl benzoate;

(9) A styrene, for example, styrene, methylstyrene, or chloromethystyrene;

(10) A vinyl ketone, for example, methyl vinyl ketone, ethyl vinyl ketone, propyl vinyl ketone, or phenyl vinyl ketone;

(11) An olefin, for example, ethylene, propylene, isobutylene, butadiene, or isoprene;

(12) N-vinylpyrrolidone, N-vinylcarbazole, or N-vinylpyridine,

(13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

(14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further another monomer may be copolymerized with the above monomer.

The above vinyl polymer can be manufactured according to a conventional solution polymerization, bulk polymerization or suspension polymerization. A polymerization initiator used is not specifically limited, but examples thereof include azo bis type radical generating agents, for example, 2,2′-azobisiso-butyronitrile (AIBN) or 2,2′-azobis(2-methylbutyronitrile. The amount used of the polymerization initiator is ordinarily from 0.05 to 10.0 part by weight (preferably from 0.1 to 5 part by weight), based on 100 parts by weight of monomer used to prepare a (co)polymer. As the solvents used in the solution polymerization, there are organic solvents including ketones, esters or aromatics, for example, good solvents generally used in the solution polymerization such as toluene, ethyl acetate, benzene, methylcellosolve, ethylcellosolve, acetone, and methyl ethyl ketone. Among these, ones having a boiling point of from 60 to 120° C. are preferred. The solution polymerization is ordinarily carried out at 40 to 120° C. (preferably 60 to 110° C.), for 3 to 10 hours (preferably 5 to 8 hours) employing the above solvents. After completion of polymerization, the solvents are removed from the resulting polymerization solution to obtain a (co)polymer. Alternatively, the polymerization solution is used without removing the solvents in a double bond incorporation reaction as described later which follows.

The molecular weight of the polymer can be adjusted by selecting solvents used or by controlling polymerization temperature. The solvents used or the polymerization temperature for obtaining a polymer with an intended molecular weight is appropriately determined by monomers used. The molecular weight of the polymer can be also adjusted by mixing the above solvents with a specific solvent. Examples of the specific solvent include mercaptans such as n-octylmercaptan, n-dodecylmercaptan, t-dodecylmercaptan and mercaptoethanol, and carbon chlorides such as carbon tetrachloride, butyl chloride and propylene chloride. The mixing ratio of the specific solvent to the solvents described above can be properly determined by monomers used, solvents used or polymerization conditions.

The polymeric binder in the invention is preferably a vinyl polymer having in the side chain a carboxyl group and a polymerizable double bond. As the polymer binder is also preferred an unsaturated bond-containing copolymer which is obtained by reacting a carboxyl group contained in the above vinyl copolymer molecule with for example, a compound having a (meth)acryloyl group and an epoxy group.

Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-27196. Further, an unsaturated bond-containing copolymer which is obtained by reacting a hydroxyl group contained in the above vinyl copolymer molecule with for example, a compound having a (meth)acryloyl group and an isocyanate group. Examples of the compound having a (meth)acryloyl group and an isocyanate group in the molecule include vinyl isocyanate, (meth)acryl isocyanate, 2-(meth)acroyloxyethyl isocyanate, m- or p-isopropenyl-α,α′-dimethylbenzyl isocyanate, and (meth)acryl isocyanate, or 2-(meth)acroyloxyethyl isocyanate is preferred.

Reaction of a carboxyl group existing in the molecule of the vinyl copolymer with a compound having in the molecule a (meth)acryloyl group and an epoxy group can be carried out according to a well-known method. For example, the reaction is carried out at a temperature of 20 to 100° C., and preferably 40 to 80° C., and more preferably at a boiling point of solvent used (while refluxing), for 2 to 10 hours and preferably 3 to 6 hours. As the solvent used in the reaction, there are solvents used in the polymerization to obtain the vinyl copolymer above. After polymerization, the solvent in the polymerization can be used without being removed from the polymerization solution as a reaction solvent used for reaction in which an aliphatic epoxy group-containing unsaturated compound is incorporated into the vinyl copolymer. The reaction can be carried out in the presence of a catalyst or a polymerization inhibitor.

As the catalyst, there are amines or ammonium chlorides. Examples of the amines include triethylamine, tributylamine, dimethylaminoethanol, diethylaminoethanol, methylamine, ethylamine, n-propylamine, i-propylamine, 3-methoxypropylamine, butylamine, allylamine, hexylamine, 2-ethylhexylamine, and benzylamine. Examples of the ammonium chlorides include triethylbenzylammonium chloride. The amount used of the catalyst is ordinarily from 0.01 to 20.0% by weight based on the weight of an aliphatic epoxy group-containing unsaturated compound used. Examples of the polymerization inhibitor include hydroquinone, hydroquinone monometyl ether, 2,5-di-t-butylhydroquinone, 2,6-di-t-butylhydroquinone, 2-methylhydroquinone, and 2-t-butylhydroquinone. The amount used of the polymerization inhibitor is ordinarily from 0.01 to 5.0% by weight based on the weight of aliphatic epoxy group-containing unsaturated compound used. The reaction process is controlled by measurement of acid value of the reaction mixture and the reaction is terminated at the time when the intended acid value is attained.

Reaction of a hydroxyl group existing in the molecule of the vinyl copolymer with a compound having in the molecule a (meth)acryloyl group and an isocyanate group can be carried out according to a known method. For example, the reaction is carried out at a temperature of 20 to 100° C., and preferably 40 to 80° C., and more preferably at a boiling point of solvent used (while refluxing), for 2 to 10 hours and preferably 3 to 6 hours. As the solvent used in the reaction, there are solvents used in the polymerization to obtain the vinyl copolymer above. After polymerization, the solvent in the polymerization can be used without being removed from the polymerization solution as a reaction solvent used for reaction in which an isocyanate group-containing unsaturated compound is incorporated into the vinyl copolymer. The reaction can be carried out in the presence of a catalyst or a polymerization inhibitor. As the catalyst, tin compounds or amines are preferably used. Examples of thereof include dibutyltin laurate, and triethylamine. The amount used of the catalyst is preferably from 0.01 to 20.0% by weight based on the weight of a double bond-containing compound used. Examples of the polymerization inhibitor include hydroquinone, hydroquinone monometyl ether, 2,5-di-t-butylhydroquinone, 2,6-di-t-butylhydroquinone, 2-methylhydroquinone, and 2-t-butylhydroquinone. The amount used of the polymerization inhibitor is ordinarily from 0.01 to 5.0% by weight based on the weight of isocyanate group-containing unsaturated compound used. The reaction process is controlled by measurement of infrared absorption spectra (IR) of the reaction mixture and the reaction is terminated at the time when the isocyanate absorption disappears.

The content of the vinyl polymer having in the side chain a carboxyl group and a polymerizable double bond is preferably from 50 to 100% by weight, and more preferably 100% by weight, based on the total weight of the polymer binder used.

The polymeric binder content of the light sensitive layer is preferably from 10 to 90% by weight, more preferably from 15 to 70% by weight, and still more preferably from 20 to 50% by weight, in view of sensitivity.

### (Sensitizing Dye Having Absorption Maximum in the Wavelength Regions of from 350 to 450 nm)

In the invention, it is preferred that the light sensitive contains a sensitizing dye having absorption maximum in the wavelength regions of 350 to 450 nm.

Examples of the dyes include cyanine, merocyanine, porphyrin, a spiro compound, ferrocene, fluorene, fulgide, imidazole, perylene, phenazine, phenothiazine, acridine, an azo compound, diphenylmethane, triphenylmethane, triphenylamine, cumarin derivatives, ketocumarin, quinacridone, indigo, styryl, pyrylium compounds, pyrromethene compounds, pyrazolotriazole compounds, benzothiazole compounds, barbituric acid derivatives, thiobarbituric acid derivatives, and ketoalcohol borate complexes.

A coumarin dye represented by the following formula (III) is especially preferred.

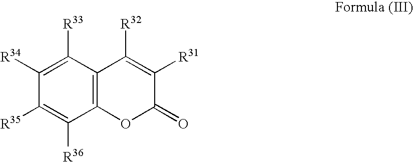

In formula (III), R³¹, R³², R³³, R³⁴, R³⁵ and R³⁶ independently represent a hydrogen atom or a substituent. Examples of the substituent include an alkyl group (for example, a methyl group, an ethyl group, a propyl group, an isopropyl group, a t-butyl group, a pentyl group, a hexyl group, an octyl group, a dodecyl group, a tridecyl group, a tetradecyl group, or a pentadecyl group), a cycloalkyl group (for example, a cyclopentyl group or a cyclohexyl group), an alkenyl group (for example, a vinyl group or a allyl group), an alkinyl group (for example, a propargyl group), an aryl group (for example, a phenyl group, or a naphthyl group), a heteroaryl group (for example, a furyl group, a thienyl group, a pyridazinyl group, a pyrimidinyl group, a pyrazinyl group, a triazinyl group, an imidazolyl group, a pyrazolyl group, a thiazolyl group, a benzimidazolyl group, a benzoxazolyl group, a quinazolyl group, or a phthalazinyl group), a saturated heterocyclic group (for example, a pyrrolidinyl group, an imidazolidinyl group, a morpholinyl group or an oxazolidinyl group), an alkoxy group (for example, a methoxy group, an ethoxy group, a propoxy group, a pentyloxy group, a hexyloxy group, an octyloxy group, or a dodecyloxy group), a cycloalkoxy group (for example, a cyclopentyloxy group, or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group, or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group, or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecycarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecycarbonyloxy group, or a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, 2-ethylhexylcarbonylamino group, an octylcarbonylamino group, a a dodecycarbonylamino group, a phenylcarbonylamino group, a naphthylcarbonylamino group, or a pyridylcarbonyl group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecyaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfonyl group), an amino group (for example, an amino group, an ethylamino group, a dimethylamino group, a butylaminocarbonyl group, a cyclopentylamino group, a 2-ethylhexylamino group, a dodecyamino group, an anilino group, a naphthylamino group, or a 2-pyridylamino group), a halogen atom (for example, fluorine, chlorine, or bromine), a cyano group, a nitro group, and a hydroxyl group. Any adjacent two of R³¹, R³², R³³, R³⁴, R³⁵ and R³⁶ may combine with each other to form a ring. R³¹, R³², R³³, R³⁴, R³⁵ and R³⁶ may be substituted or unsubstituted and the substituents of the substituted R³¹, R³², R³³, R³⁴, R³⁵ and R³⁶ include the same as those denoted above.

Coumarin dyes are preferred in which in formula (8), R³⁵ is an amino group or a substituted amino group such as an alkylamino group, a dialkylamino group, an arylamino group, a diarylamino group, or an alkylarylamino group. The coumarin compounds are preferably used in which the alkyl substituent of the substituted amino group in R³⁵ combines with R³⁴ or R³⁶ to form a ring.

Coumarin dyes are more preferred in which in addition to the above, at least one of R³¹ and R³² is an alkyl group (for example, a methyl group, an ethyl group, a propyl group, an isopropyl group, a t-butyl group, a pentyl group, a hexyl group, an octyl group, a dodecyl group, a tridecyl group, a tetradecyl group, or a pentadecyl group), a cycloalkyl group (for example, a cyclopentyl group or a cyclohexyl group), an alkenyl group (for example, a vinyl group or an allyl group), an aryl group (for example, a phenyl group, or a naphthyl group), a heteroaryl group (for example, a furyl group, a thienyl group, a pyridazinyl group, a pyrimidinyl group, a pyrazinyl group, a triazinyl group, an imidazolyl group, a pyrazolyl group, a thiazolyl group, a benzimidazolyl group, a benzoxazolyl group, a quinazolyl group, or a phthalazinyl group), a saturated heterocyclic group (for example, a pyrrolidinyl group, an imidazolidinyl group, a morpholinyl group or an oxazolidinyl group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group, or a naphthyloxycarbonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecycarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecycarbonyloxy group, or a phenylcarbonyloxy group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecyaminocarbonyl group, a phenylaminocarbonyl group, a naphthylaminocarbonyl group, or a 2-pyridylaminocarbonyl group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfonyl group), a halogen atom (for example, fluorine, chlorine, or bromine), a cyano group, a nitro group or a halogenated alkyl group (for example, a trifluoromethyl group, a tribromomethyl group, or a trichloromethyl group).

Preferred examples will be listed below, but the invention is not limited thereto.

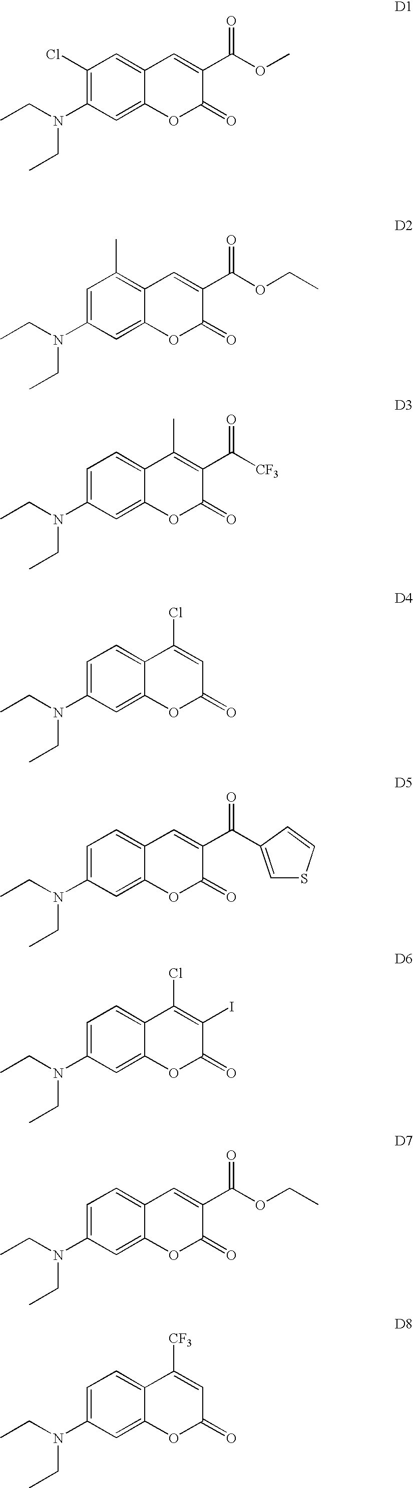

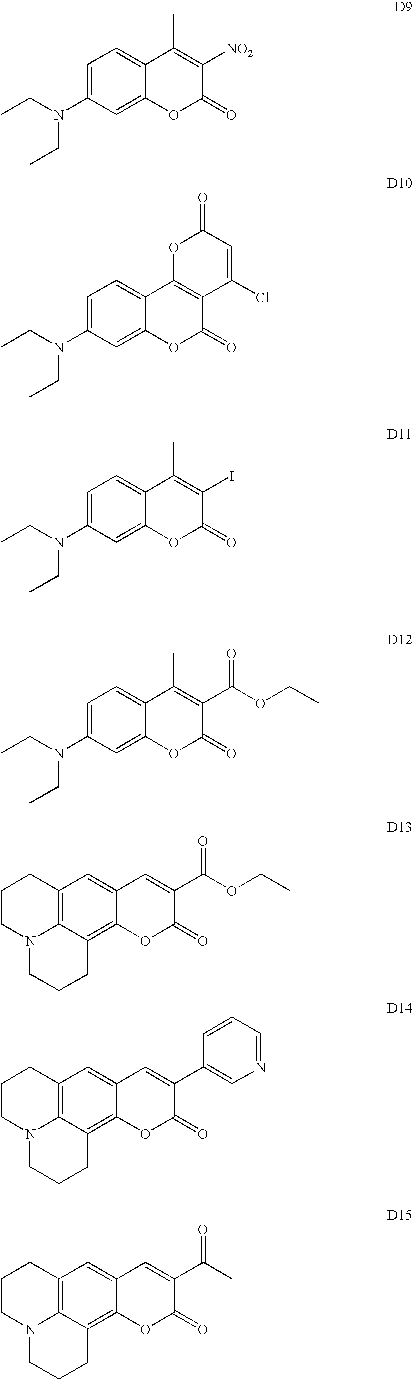

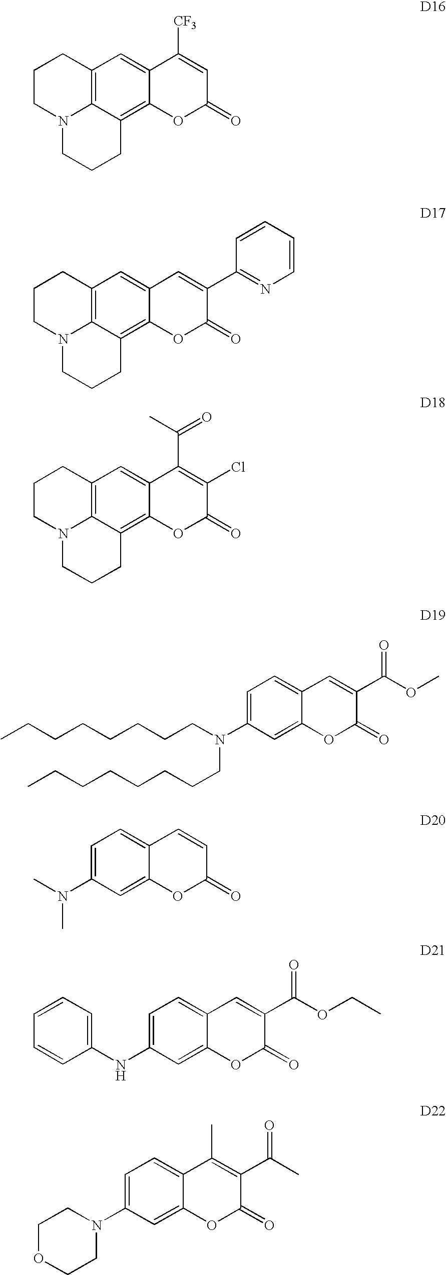

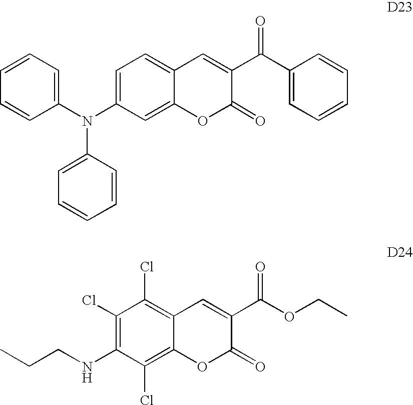

Besides the examples described above, there can be used coumarin derivatives B-1 through B-22 disclosed in Japanese Patent O.P.I. Publication No. 8-129258, coumarin derivatives D-1 through D-32 disclosed in Japanese Patent O.P.I. Publication No. 2003-12901, coumarin derivatives 1 through 21 disclosed in Japanese Patent O.P.I. Publication No. 2002-363206, coumarin derivatives 1 through 40 disclosed in Japanese Patent O.P.I. Publication No. 2002-363207, coumarin derivatives 1 through 34 disclosed in Japanese Patent O.P.I. Publication No. 2002-363208, or coumarin derivatives 1 through 56 disclosed in Japanese Patent O.P.I. Publication No. 2002-363209.

The sensitizing dye content of the light sensitive layer is preferably from 0.1 to 20% by weight, and more preferably from 0.1 to 10% by weight.

In the invention, the thickness of the negative working light sensitive layer is preferably from 0.5 to 5.0 g/m², and more preferably from 1.0 to 3.0 g/m².

Various additives which can be contained in the light sensitive layer described above, a support, a protective layer, a coating method of a light sensitive layer coating liquid on the support and a manufacturing method of a light sensitive planographic printing plate material will be explained below.

### (Various Additives)

The light sensitive layer in the invention is preferably added with a polymerization inhibitor, in order to prevent undesired polymerization of the ethylenically unsaturated compound during the manufacture or after storage of light sensitive planographic printing plate material. Examples of the polymerization inhibitor include hydroquinone, p-methoxyphenol, di-t-butyl-p-cresol, pyrrogallol, t-butylcatechol, benzoquinone, 4,4′-thiobis (3-methyl-6-t-butylphenol), 2,2′-methylenebis (4-methyl-6-t-butylphenol), N-nitrosophenylhydroxylamine cerous salt, and 2-t-butyl-6-(2-t-butyl-6-hydroxy-5-methylbenzyl)-4-methylphenyl acrylate.

The polymerization inhibitor content is preferably 0.01 to 5% by weight based on the total solid content of the light sensitive layer. Further, in order to prevent undesired polymerization induced by oxygen, behenic acid or a higher fatty acid derivative such as behenic amide may be added to the layer. After the light sensitive layer is coated layer, the coated layer may be dried so that the higher fatty acid derivative is localized at the vicinity of the surface of the light sensitive layer. The content of the higher fatty acid derivative is preferably 0.5 to 10% by weight, based on the total solid content of the light sensitive layer.

A colorant can be also used. As the colorant can be used known materials including commercially available materials. Examples of the colorant include those described in revised edition “Ganryo Binran”, edited by Nippon Ganryo Gijutu Kyoukai (publishe by Seibunndou Sinkosha), or “Color Index Binran”. Pigment is preferred.

Kinds of the pigment include black pigment, yellow pigment, red pigment, brown pigment, violet pigment, blue pigment, green pigment, fluorescent pigment, and metal powder pigment. Examples of the pigment include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment).

Among these pigment, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment content is preferably 0.1 to 10% by weight, and more preferably 0.2 to 5% by weight, based on the total solid content of the photopolymerizable light sensitive layer composition.

A purple pigment or a blue pigment is preferably utilized in view of absorption of light with the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone BC. Among them, more preferable are Phthalocyanine Blue and Dioxane Violet.

The light sensitive layer can contain surfactants as a coating improving agent as long as the performance of the invention is not jeopardized. Among these surfactants, a fluorine-contained surfactant is preferred.

Further, in order to improve physical properties of the cured light sensitive layer, the layer can contain an inorganic filler or a plasticizer such as dioctyl phthalate, dimethyl phthalate or tricresyl phosphate. The content of such a material is preferably not more than 10% by weight, based on the total solid content of the light sensitive layer.

### Preparation of Light Sensitive Planographic Pringing Plate Material

### (Preparation of Light Sensitive Layer Coating Solution)

The light sensitive planographic printing plate material in the invention is manufactured by preparing a light sensitive layer coating solution containing the above-described components, then coating the light sensitive layer coating solution on an aluminum support as described later and drying to form a light sensitive layer on the support.

The solvents used in the preparation of the light sensitive layer coating solution include an alcohol such as sec-butanol, isobutanol, n-hexanol, or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

### (Coating)

In the invention, the above-described light sensitive layer coating solution is coated on the support according to a coating conventional method, and dried to prepare a light sensitive planographic printing plate material. Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method. A drying temperature of the coated light sensitive layer is preferably from 60 to 160° C., more preferably from 80 to 140° C., and still more preferably from 90 to 120° C., in view of printing durability and an anti-stain property.

### Protective Layer (Oxygen Shielding Layer)

In the invention, a protective layer is preferably provided on the light sensitive layer.

It is preferred that the protective layer (oxygen shielding layer) is highly soluble in the developer as described later (generally an alkaline solution) . Polyvinyl alcohol or polyvinyl pyrrolidone is preferably used in the protective layer. Polyvinyl alcohol has the effect of preventing oxygen from transmitting and polyvinyl pyrrolidone has the effect of increasing adhesion between the oxygen shielding layer and the light sensitive layer.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

In the planographic printing plate material in the invention, adhesive strength between the protective layer and the light sensitive layer is preferably not less than 35 mN/mm, more preferably not less than 50 mN/mm, and still more preferably not less than 75 mN/mm. Preferred composition of the protective layer is disclosed in Japanese Patent Application No. 8-161645.

The adhesive strength can be determined according to the following method. The adhesive tape with a sufficient adhesive force is applied on the protective layer, and then peeled together with the protective layer under the applied tape in the normal direction relative to the protective layer surface. Force necessary to peel the tape together with the protective layer is defined as adhesive strength.

The protective layer may further contain a surfactant or a matting agent. The protective layer is formed, coating on the photopolymerizable light sensitive layer a protective layer coating solution in which the above protective layer composition is dissolved in an appropriate coating solvent, and drying. The main solvent of the coating solution is preferably water or an alcohol solvent such as methanol, ethanol, or iso-propanol. The coating method of the protective layer coating solution is the same as those described above of the light sensitive layer coating solution.

The dry thickness of the protective layer is preferably 0.1 to 5.0 μm, and more preferably 0.5 to 3.0 μm.

### (Support)

As the support in the invention, an aluminum support having a hydrophilic surface is used, and may be a support 92 8139 made of pure aluminum or an aluminum alloy. As the aluminum alloy, there can be used various ones including an alloy of aluminum and a metal such as silicon, copper, manganese, magnesium, chromium, zinc, lead, bismuth, nickel, titanium, sodium or iron.

It is preferable that an aluminum plate for the support in the invention is subjected to degreasing treatment for removing rolling oil prior to surface roughening (graining). The degreasing treatments include degreasing treatment employing solvents such as trichlene and thinner, and emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting plate is preferably subjected to desmut treatment in an aqueous solution of an acid such as phosphoric acid, nitric acid, sulfuric acid, chromic acid, or a mixture thereof, since smut is produced on the surface of the plate.

Subsequently, surface roughening is carried out. In the invention, electrolytic surface roughening is carried out, but prior to the electrolytic surface roughening, mechanical surface roughening can be carried out.

Though there is no restriction for the mechanical surface roughening method, a brushing roughening method and a honing roughening method are preferable. The brushing roughening method is carried out by rubbing the surface of the support with a rotating brush with a brush hair with a diameter of 0.2 to 0.8 mm, while supplying slurry in which volcanic ash particles with a particle size of 10 to 100 μm are dispersed in water to the surface of the support. The honing roughening method is carried out by ejecting obliquely slurry with pressure applied from nozzles to the surface of the support, the slurry containing volcanic ash particles with a particle size of 10 to 100 μm dispersed in water. A surface roughening can be also carried out by laminating the plate surface with a sheet on the surface of which abrading particles with a particle size of from 10 to 100 μm was coated at intervals of 100 to 200 μm and at a density of 2.5×10³ to 10×10³/cm², and applying pressure to the sheet to transfer the roughened pattern of the sheet and roughen the surface of the plate.

After the plate has been mechanically roughened as above, it is preferably dipped in an acid or an aqueous alkali solution in order to remove abrasives and aluminum dust, etc. which have been embedded in the surface of the plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, an aqueous alkali solution of for example, sodium hydroxide is preferably used. The dissolution amount of aluminum is preferably 0.5 to 5 g/m². After the support has been dipped in the aqueous alkali solution, it is preferable for the plate to be dipped in an acid such as phosphoric acid, nitric acid, sulfuric acid and chromic acid, or in a mixed acid thereof, for neutralization.

The electrolytic surface roughening is carried out in an acidic electrolytic solution. As the acidic electrolytic solution, a 0.4 to 2.8% by weight hydrochloric acid or nitric acid solution is used. The concentration of hydrochloric acid or nitric acid in the electrolytic solution is preferably from 1 to 2.3% by weight. The electrolytic surface roughening is carried at a current density (in terms of effective value) of from 30 to 100 A/dm² for 10 to 120 seconds. The current density is preferably from 30 to 80 A/dm², and more preferably from 40 to 75 A/dm².

Electrolytic surface roughening temperature, although not specifically limited, is preferably from 5 to 80° C., and more preferably from 10 to 60° C. Although not specifically limited also, voltage applied is preferably from 1 to 50 V, more preferably from 10 to 30 V, and still more preferably from 1 to 50 V. Although not specifically limited also, quantity of electricity applied is preferably from 100 to 5000 C/dm², and more preferably from 100 to 2000 C/dm².

It is possible to optionally add, to the electrolytic solution, nitrates, chlorides, amines, aldehydes, phosphoric acid, chromic acid, boric acid, acetic acid or oxalic acid.

After the plate has been electrolytically surface roughened as above, it is preferably dipped in an acid or an aqueous alkali solution in order to remove aluminum dust, etc. produced in the surface of the plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum is preferably 0.5 to 5 g/m². After the plate has been dipped in the aqueous alkali solution, it is preferable for the plate to be dipped in an acid such as phosphoric acid, nitric acid, sulfuric acid and chromic acid, or in a mixed acid thereof, for neutralization.

After the surface roughening, anodizing treatment may be carried out. There is no restriction in particular for the method of anodizing treatment used in the invention, and known methods can be used. The anodizing treatment forms an anodization film on the surface of the aluminum plate. For the anodizing treatment there is preferably used a method of applying a current density of from 1 to 10 A/dm² to an aqueous solution containing sulfuric acid and/or phosphoric acid in a concentration of from 10 to 50%, as an electrolytic solution. However, it is also possible to use a method of applying a high current density to sulfuric acid as described in U.S. Pat. No. 1,412,768, a method to electrolytically etching the support in phosphoric acid as described in U.S. Pat. No. 3,511,661, or a method of employing a solution containing two or more kinds of chromic acid, oxalic acid, malonic acid, etc. The coated amount of the formed anodization film is suitably 1 to 50 mg/dm², and preferably 10 to 40 mg/dm². The coated amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water.

It is preferred that the anodized aluminum plate is treated with an aqueous sodium silicate solution at preferably from 20 to 50° C., and more preferably from 20 to 45° C. Although not specifically limited, the concentration of sodium silicate in the aqueous sodium silicate solution is preferably from 0.01 to 35% by weight, and more preferably from 0.1 to 5 by weight.

It is preferred that the anodized aluminum plate is preferably treated with an aqueous polyvinyl phosphonic acid solution at preferably from 20 to 70° C., and more preferably from 30 to 65° C. Although not specifically limited, the concentration of polyvinyl phosphonic acid in the aqueous polyvinyl phosphonic acid solution is preferably from 0.01 to 35% by weight, and more preferably from 0.1 to 5 by weight.

### EXAMPLES

Next, the present invention will be explained in the following examples, but the present invention is not limited thereto. In the examples, “parts” represents “parts by weight”, unless otherwise specified.

### Example 1

### Polymeric Binder: Synthesis of Acryl Copolymer 1

Thirty parts of methacrylic acid, 50 parts of methyl methacrylate, 20 parts of ethyl methacrylate, 500 parts of isopropyl alcohol, and 3 parts of α,α′-azobisisobutyro-nitrile were put in a three neck flask under nitrogen atmosphere, and reacted under nitrogen atmosphere for 6 hours at 80° C. in an oil bath. After that, the reaction mixture was refluxed at a boiling point of isopropyl alcohol for one hour, and 3 parts of triethylammonium chloride and 25 parts of glycidyl methacrylate were further added to the mixture, and reacted for additional 3 hours. Thus, acryl copolymer 1 was obtained. The weight average molecular weight of the acryl copolymer 1 was 35,000, measured according to GPC. The glass transition temperature Tg of the acryl copolymer 1 was 85° C., measured according to DSC (differential thermal analysis).

### (Preparation of Support)

A 0.30 mm thick and 1030 mm wide aluminum plate (material JIS A 1050) was successively treated according to the following procedures:

(a) The aluminum plate was subjected to etching treatment, in which the aluminum plate was sprayed with a 70° C. solution having a caustic soda concentration of 2.6 weight % and an aluminum ion concentration of 6.5 weight % to dissolve the aluminum by 0.3 g/m², and was washed by means of a water spray.

(b) Desmut treatment was performed by spraying the aluminum plate with an aqueous 1% by weight nitric acid solution (containing aluminum ion of 0.5 weight %) at 30° C., followed by washing by a water spray.

(c) The resulting aluminum plate was subjected to continuous electrolytic roughening treatment, utilizing an alternating voltage of 60 Hz, in a 21° C. electrolytic solution containing 1.1% by weight hydrochloric acid, 0.5% by weight of an aluminum ion and 0.007% by weight of acetic acid, and was washed by water spray. The electrolytic roughening treatment was performed employing a sine wave alternating current at a TP (time taken for current to reach from zero to the peak value) of 2 msec, and employing a carbon electrode as a counter electrode, wherein the current density was 50 A/dm² in terms of effective value, and the quantity of electricity supplied was 900 C/dm².

(d) The resulting aluminum plate was desmutted for 10 seconds in an aqueous 20% by weight phosphoric acid solution having an aluminum ion concentration of 0.5% by weight at 60° C., and washed with water spray.

(e) Employing a conventional anodizing treatment apparatus employing a two-step power-supplied electrolysis method (in which a length of each of the first and second electrolysis section is 6 m, the first power supply section is 3 m long, the second power supply section is 3 m long, and a length of each of the first and second power supply electrodes is 2.4 m), anodizing treatment was performed at 38° C. in a solution having a sulfuric acid concentration of 170 g/l (having an aluminum ion concentration of 0.5 weight %) in the electrolysis section. Thereafter, the plate was sprayed with water and washed. At this time, in the anodizing treatment apparatus, electric current from power source flowed to the first power supply electrode arranged in the first power supply section, then to the aluminum plate through the electrolytic solution to form an oxidized film on the surface of the aluminum plate in the first electrolysis section, and passed through the electrolysis electrode arranged in the first power supply section to return to the power source. On the other hand, electric current from a power source flowed to the second power supply electrode arranged in the second power supply section, then similarly to the aluminum plate through the electrolytic solution to form an oxidized film on the surface of the aluminum plate in the second electrolysis section. The quantity of electricity supplied from a power source to the first power supply section and the quantity of electricity supplied from a power source to the second power supply section were same, and the power supply electric current density on the oxidized film surface at the second power supply section was approximately 25 A/dm². In the second power supply section, power was supplied from the surface of the oxidized film of 1.35 g/m². The final amount of the oxidized film was 2.7 g/m². The resulting aluminum plate was washed with water, then subjected to hydrophilization treatment in which the plate was immersed in a 75° C. aqueous 0.4% by weight polyvinyl phosphonic acid solution for 30 seconds, washed with water, and dried with an infrared heater. Thus, an aluminum support was obtained. The aluminum support obtained above had a centerline average surface roughness (Ra) of 0.55 μm.

### (Preparation of Light Sensitive Planographic Printing Plate Material Sample 1)

The following photopolymerizable light sensitive layer coating solution 1 was coated on the resulting support through a wire bar, and dried at 95° C. for 1.5 minutes to give a light sensitive layer having a dry thickness of 1.5 g/m². After that, the following oxygen shielding layer coating solution 1 was coated on the photopolymerizable light sensitive layer using a wire bar, and dried at 75° C. for 1.5 minutes to give an oxygen shielding layer with a dry thickness of 1.8 g/m². Thus, a light sensitive planographic printing plate material sample 1 was prepared.

### (Photopolymerizable Light Sensitive Layer Coating Solution 1)

| | | |
|---|---|---|
| Ethylenically unsaturated compound 1–17 | 27.0 | parts |
| Ethylenically unsaturated compound | 14.0 | parts |
| (NK ESTER 4G, produced by Shinnakamura | | |
| Kagaku Co., Ltd) | | |
| Spectral Sensitizing Dye (D7) | 3 | parts |
| 2,2′-Bis(chlorophenyl)-4,4′,5,5′- | 4.0 | parts |
| tetraphenylbiimidazole | | |
| 2-Mercaptobenzothiazole | 2.0 | parts |
| Acryl copolymer 1 | 42.0 | parts |
| Phthalocyanine pigment | 6.0 | parts |
| (MHI 454, produced by Mikuni Shikiso Co., Ltd.) | | |
| 2-t-Butyl-6-(3-t-butyl-2-hydroxy-5- | 0.5 | parts |
| methylbenzyl)-4-methylphenylacrylate | | |
| (Sumirizer GS: produced by Sumitomo 3M Co., Ltd.) | | |
| Fluorine-contained surfactant | 0.5 | parts |
| (FC-4430: produced by Sumitomo 3M Co., Ltd.) | | |
| Siloxane surfactant | 0.9 | parts |
| (BYK337, produced by BYK Chemie Co., Ltd.) | | |
| Methyl ethyl ketone | 80 | parts |
| Propylene glycol methyl ether | 820 | parts |
| (Oxygen shielding layer coating solution) | | |
| Polyvinyl alcohol (GL-05, produced | 79 | parts |
| by Nippon Gosei Kagaku Co., Ltd.) | | |
| Polyvinyl Pyrrolidone (PVP K-30, | 10 | parts |
| produced by ISP Japan Co., Ltd.) | | |
| Polyethylene imine (Lupasol WF, available from | 5 | parts |
| BASF Co., Ltd.) | | |
| Cationically modified polyvinyl alcohol | 5 | parts |
| (Kuraray C Polymer, produced b Kuraray Co., Ltd.) | | |
| Surfactant (Surfinol 465, | 0.5 | parts |
| produced by Nisshin Kagaku Kogyo Co., Ltd.) | | |
| Water | 900 | parts |

A developer having the following composition was prepared.

### <Composition of Developer>

| | |
|---|---|
| Potassium silicate No. A | 8.0% by weight |
| Newcol B-13SN (produced by | 2.0% by weight |
| Nippon Nyukazai Co., Ltd.) | |
| Pronon #204 (produced by | 1.0% by weight |
| Nippon Yushi Co., Ltd.) | |
| Potassium hydroxide | amount giving pH 12.9 |

### (Evaluation)

Employing a plate setter (produced by ECRM Co., Ltd.) installed with a light source emitting a 405 nm light, the light sensitive planographic printing plate material sample 1 obtained above was imagewise exposed at a resolving degree of 2400 dpi, so that exposure energy on the plate surface was 50 μJ/cm². Herein, dpi represents the dot numbers per 2.54 cm.

The exposed sample was processed under processing condition I, II, III or IV as described later, employing a CTP automatic developing machine (Raptor 85 Polymer, produced by Glunz & Jensen Co., Ltd.) to obtain a planographic printing plate. Herein, the developing machine comprised a preheating section (provided with an IR heater) for preheating the exposed sample, a pre-washing section for removing the oxygen shielding layer before development, a development section charged with the developer as obtained above, a post-washing section for removing the developer remaining on the developed sample after development, and a gumming section charged with a gumming solution (a solution obtained by diluting GW-3, produced by Mitsubishi Chemical Co., Ltd., with water by a factor of 2) for protecting the surface of the developed sample. Thus, a planographic printing plate sample to be used for printing was obtained. Processing Condition I (Comparative):

Employing the CTP automatic developing machine Raptor 85 Polymer, the exposed sample was heated in the preheating section (IR heater) for 20 seconds at a temperature as shown in Table 1, and processed.

### Processing Condition II (Inventive):

The exposed sample was induction heated in an induction heater for 20 seconds at a temperature as shown in Table 1, and then processed employing the CTP automatic developing machine Raptor 85 Polymer, wherein the preheating section (IR heater) was switched off so that the sample was not heated therein.

### Processing Condition III (Comparative):

The exposed sample was processed employing the CTP automatic developing machine Raptor 85 Polymer, provided that the preheating section (IR heater) was switched off so that the sample was not heated therein, and gumming treatment was not carried out in the gumming section. The resulting sample was heated for 20 seconds at a temperature as shown in Table 1 in the preheating section (IR heater) of the CTP automatic developing machine, and then subjected to gumming treatment in the gumming section of the CTP automatic developing machine.

### Processing Condition IV (Inventive):

The exposed sample was processed employing the CTP automatic developing machine Raptor 85 Polymer, provided that the preheating section (IR heater) was switched off so that the sample was not heated therein, and gumming treatment was not carried out in the gumming section. The resulting sample was induction heated in an induction heater for 20 seconds at a temperature as shown in Table 1, and then subjected to gumming treatment in the gumming section of the CTP automatic developing machine.

Thermo labels were used for confirming the heating temperatures.

The induction heating was carried out employing a high frequency oscillator SFT series, a high frequency transformer, a chilled water circulation cooler, and a heating coil each available from Shimada Rika Co., Ltd. The frequency used was 100 kHz, and the high frequency oscillator was activated only when the sample was passed in the heating coil.

### (Dot Gain)

The light sensitive planographic printing plate material sample obtained above was exposed under conditions of 2400 dpi and a screen line number of 175 so as to obtain an image with a dot area of 40%, and processed under the conditions as described above to obtain a planographic printing plate sample. The dot area on the resulting planographic printing plate sample was measured employing a dot area measuring apparatus ccDot produced by SDC Co., Ltd. Values obtained by subtracting 40(%) from the measurements are shown in Table 1. A value closer to zero is preferred, and shows that dot gain is smaller.

### (Printing Durability

Employing the resulting printing plate, printing was carried out on a press (DAIYA1F-1 produced by Mitsubishi Jukogyo Co., Ltd.), wherein a coat paper, printing ink (Toyo King Highecho Magenta M” produced by Toyo Ink Manufacturing Co., Ltd.), and dampening water (SG-51, H solution produced by Tokyo Ink Co., Ltd., Concentration: 1.5%) were used. Printing cycle was repeated in which when seven hundred copies were printed, printing was stopped, then the printing plate surface was wiped with a plate cleaner, and printing was restarted. Herein, every time seven hundred copies were printed, dots at highlight portions and at shadow portions of the copies were observed. This printing cycle has been repeated, and the number of the printing cycles, at which the dot reduction at highlight portions (image area with a dot area of 30%) and/or filling-up at shadow portions (image area with a dot area of 80%) occurred, was defined as a measure of printing durability. A printing cycle number of 1 means that seven hundred copies were printed, and the printing plate surface was wiped with a plate cleaner. The more the printing cycle number is, the higher the printing durability. The plate cleaner used was Ultra Plate Cleaner (available from Dainichi Seika Co., Ltd.).

The results are shown in Table 1.

TABLE 1

| | Processing | | | |
|---|---|---|---|---|
| | Condition | Dot | Printing | |
| Processing | (Heating | Gain | Cycle | |
| No. | Temperature) | (%) | Number | Remarks |
| 1 | I (50° C.) | −30 | 0 | Comparative |
| 2 | I (80° C.) | 19 | 20 | Comparative |
| 3 | I (100° C.) | 20 | 40 | Comparative |
| 4 | I (120° C.) | 26 | 44 | Comparative |
| 5 | I (150° C.) | 28 | 50 | Comparative |
| 6 | I (180° C.) | 30 | 55 | Comparative |
| 7 | II (50° C.) | −28 | 0 | Comparative |
| 8 | II (80° C.) | 18 | 40 | Inventive |
| 9 | II (100° C.) | 17 | 46 | Inventive |
| 10 | II (120° C.) | 20 | 52 | Inventive |
| 11 | II (150° C.) | 21 | 58 | Inventive |
| 12 | II (180° C.) | 24 | 62 | Inventive |
| 13 | III (50° C.) | −35 | 0 | Comparative |
| 14 | III (80° C.) | 10 | 17 | Comparative |
| 15 | III (100° C.) | 10 | 30 | Comparative |
| 16 | III (120° C.) | 11 | 32 | Comparative |
| 17 | III (150° C.) | 12 | 35 | Comparative |
| 18 | III (180° C.) | 14 | 37 | Comparative |
| 19 | IV (50° C.) | −32 | 0 | Comparative |
| 20 | IV (80° C.) | 8 | 38 | Inventive |
| 21 | IV (100° C.) | 8 | 45 | Inventive |
| 22 | IV (120° C.) | 9 | 49 | Inventive |
| 23 | IV (150° C.) | 10 | 52 | Inventive |
| 24 | IV (180° C.) | 11 | 56 | Inventive |

As is apparent from Table 1, the inventive processing method provides reduced dot gain and high printing durability.

### Example 2

### (Preparation of Light Sensitive Planographic Printing Plate Material Sample 2)

A light sensitive planographic printing plate material sample 2 was prepared in the same manner as in Example 1 of the Specification, except that the following photopolymerizable light sensitive layer coating solution 2 was used instead of the photopolymerizable light sensitive layer coating solution 1.

### (Photopolymerizable Light Sensitive Layer Coating Solution 2)

| | | |
|---|---|---|
| Ethylenically unsaturated compound 1–17 | 27.0 | parts |
| Ethylenically unsaturated compound | 14.0 | parts |
| (NK ESTER 4G, produced by Shinnakamura | | |
| Kagaku Co., Ltd) | | |
| Spectral Sensitizing Dye (D7) | 3 | parts |
| 2,2′-Bis(chlorophenyl)-4,4′,5,5′- | 4.0 | parts |
| tetraphenylbiimidazole | | |
| Polyhalogen compound as shown in Table 2 | 3.0 | parts |
| Acryl copolymer 1 | 42.0 | parts |
| Phthalocyanine pigment | 6.0 | parts |
| (MHI 454, produced by Mikuni Shikiso Co., Ltd.) | | |
| 2-t-Butyl-6-(3-t-butyl-2-hydroxy-5- | 0.5 | parts |
| methylbenzyl)-4-methylphenylacrylate | | |
| (Sumirizer GS: produced by Sumitomo 3M Co., Ltd.) | | |
| Fluorine-contained surfactant | 0.5 | parts |
| (FC-4430: produced by Sumitomo 3M Co., Ltd.) | | |
| Siloxane surfactant | 0.9 | parts |
| (BYK337, produced by BYK Chemie Co., Ltd.) | | |
| Methyl ethyl ketone | 80 | parts |
| Propylene glycol methyl ether | 820 | parts |

### (Evaluation)

The light sensitive planographic printing plate material sample 2 obtained above was processed in the same manner as in Example 1 above, except that the heating temperature in the processing conditions I, II, III and IV was 120° C., and evaluated in the same manner as in Example 1 of the Specification. The results are shown in Table 2.

TABLE 2

| | | Processing | | | |
|---|---|---|---|---|---|
| | | Condition | Dot | Printing | |
| Processing | Polyhalogen | (Heating | Gain | Cycle | |
| No. | Compound | Temperature) | (%) | Number | Remarks |
| 25 | None | I (120° C.) | 27 | 45 | Comp. |
| 26 | BR43 | I (120° C.) | 28 | 47 | Comp. |
| 27 | BR67 | I (120° C.) | 28 | 48 | Comp. |
| 28 | *Triazine 1 | I (120° C.) | 28 | 47 | Comp. |
| 29 | None | I (120° C.) | 21 | 53 | Inv. |
| 30 | BR43 | I (120° C.) | 21 | 60 | Inv. |
| 31 | BR67 | II (120° C.) | 21 | 60 | Inv. |
| 32 | *Triazine 1 | II (120° C.) | 21 | 62 | Inv. |
| 33 | None | II (120° C.) | 12 | 34 | Comp. |
| 34 | BR43 | II (120° C.) | 12 | 35 | Comp. |
| 35 | BR67 | II (120° C.) | 13 | 34 | Comp. |
| 36 | *Triazine 1 | II (120° C.) | 13 | 35 | Comp. |
| 37 | None | III (120° C.) | 11 | 51 | Inv. |
| 38 | BR43 | III (120° C.) | 11 | 58 | Inv. |
| 39 | BR67 | III (120° C.) | 11 | 58 | Inv. |
| 40 | *Triazine 1 | III (120° C.) | 11 | 57 | Inv. |

Comp.: Comparative,
Inv.: Inventive
*Triazine 1: 2-Phenyl-4,6-bis(trichloromethyl)-s-triazine

As is apparent from Table 2, the inventive processing method of a light sensitive planographic printing plate material comprising a light sensitive layer containing a polyhalogen compound provides reduced dot gain and high printing durability.

What is claimed is:

1. A processing method of a light sensitive planographic printing plate material comprising an aluminum support and provided thereon, a light sensitive layer containing an ethylenically unsaturated compound, a photopolymerization initiator, and a polymeric binder, the method comprising the steps of:
imagewise exposing the light sensitive planographic printing plate material;
induction heating the exposed light sensitive planographic printing plate material at a temperature of from 65 to 200° C., employing an induction heater; and
developing the heated light sensitive planographic printing plate material.

2. The processing method of claim 1, wherein said imagewise exposing is carried out, employing a laser emitting light with an emission wavelength of from 350 to 450 nm.

3. The processing method of claim 1, wherein said induction heating is carried out for from 5 to 30 seconds.

4. The processing method of claim 1, wherein the photopolymerization initiator is a biimidazole compound.

5. The processing method of claim 1, wherein the photopolymerization initiator is a polyhalogen compound.

6. The processing method of claim 5, wherein the polyhalogen compound is a polyhaloacetyl compound represented by the following formula (I),
R¹¹—-C(X¹⁰)₂—(C═O)—R¹² Formula (I)
wherein X¹⁰ represents a chlorine atom or a bromine atom; R¹¹ represents a hydrogen atom, a chlorine atom, a bromine atom, an alkyl group, an aryl group, an acyl group, an alkylsulfonyl group, an arylsulfonyl group or a cyano group; and R¹² represents a monovalent substituent, provided that R¹¹ and R¹² may combine with each other to form a ring.

7. The processing method of claim 1, wherein the light sensitive layer further contains a coumarin dye represented by the following formula (III), 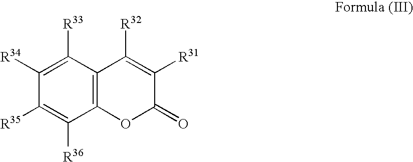
wherein R³¹, R³², R³³, R³⁴, R³⁵ and R³⁶ independently represent a hydrogen atom, an alkyl group, a cycloalkyl group, an alkenyl group, an alkinyl group, an aryl group, a heteroaryl group, a saturated heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sulfinyl group, an alkylsulfonyl group, an arylsulfonyl group, an amino group, a halogen atom, a cyano group, a nitro group or a hydroxyl group, provided that any adjacent two of R³¹, R³², R³³, R³⁴, R³⁵ and R³⁶ may combine with each other to form a ring.

8. A processing method of a light sensitive planographic printing plate material comprising an aluminum support and provided thereon, a light sensitive layer containing an ethylenically unsaturated compound, a photopolymerization initiator, and a polymeric binder, the method comprising the steps of:
imagewise exposing the light sensitive planographic printing plate material;
developing the exposed light sensitive planographic printing plate material; and
induction heating the developed light sensitive planographic printing plate material to a temperature of from 65 to 200° C., employing an induction heater.

9. The processing method of claim 8, wherein said imagewise exposing is carried out, employing a laser emitting light with an emission wavelength of from 350 to 450 nm.

10. The processing method of claim 8, wherein said induction heating is carried out for from 5 to 30 seconds.

11. The processing method of claim 8, wherein the photopolymerization initiator is a biimidazole compound.

12. The processing method of claim 8, wherein the photopolymerization initiator is a polyhalogen compound.

13. The processing method of claim 12, wherein the polyhalogen compound is a polyhaloacetyl compound represented by the following formula (I),
R¹¹—C(X¹⁰)₂—(C═O)—R¹² Formula (I)
wherein X¹⁰ represents a chlorine atom or a bromine atom; R¹¹ represents a hydrogen atom, a chlorine atom, a bromine atom, an alkyl group, an aryl group, an acyl group, an alkylsulfonyl group, an arylsulfonyl group or a cyano group; and R¹² represents a monovalent substituent, provided that R¹¹ and R¹² may combine with each other to form a ring.

14. The processing method of claim 8, wherein the light sensitive layer further contains a coumarin dye represented by the following formula (III), 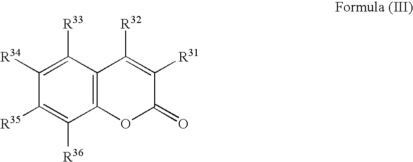
wherein R³¹, R³², R³³ R³⁴, R³⁵ and R³⁶ independently represent a hydrogen atom, an alkyl group, a cycloalkyl group, an alkenyl group, an alkinyl group, an aryl group, a heteroaryl group, a saturated heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sulfinyl group, an alkylsulfonyl group, an arylsulfonyl group, an amino group, a halogen atom, a cyano group, a nitro group or a hydroxyl group, provided that any adjacent two of R³¹, R³², R³³, R³⁴, R³⁵ and R³⁶ may combine with each other to form a ring.
